(19) United States
(12) Patent Application Publication
(10) Pub. No.: US 2016/0324038 A1
(43) Pub. Date: Nov. 3, 2016

(54) CONTROL METHOD, INFORMATION PROCESSING SYSTEM, AND STORAGE MEDIUM

(71) Applicant: FUJITSU LIMITED, Kawasaki-shi (JP)

(72) Inventor: Akira HIRAI, Kawasaki (JP)

(73) Assignee: FUJITSU LIMITED, Kawasaki-shi (JP)

(21) Appl. No.: 15/071,843

(22) Filed: Mar. 16, 2016

(30) Foreign Application Priority Data
Apr. 30, 2015 (JP) 2015-092495

(51) Int. Cl. H05K 7/20; G05B 15/02

(52) U.S. Cl. CPC H05K 7/20836; G05B 15/02

(57) ABSTRACT

A control method executed by an information processing system that includes a plurality of electronic devices arranged side by side in a single direction in a common housing and having temperature sensors and includes a managing device coupled to the plurality of electronic devices, the control method includes activating an electronic device among the plurality of electronic devices based on a predetermined order; receiving temperature information from the temperature sensors included in the plurality of electronic devices, the temperature information indicating temperatures of the plurality of electronic devices that are measured when any of the plurality of electronic devices operates and another one or more electronic devices excluding the operating electronic device do not operate; and identifying positions of the plurality of electronic devices arranged in the common housing, based on amounts of changes in temperatures of the plurality of electronic devices calculated using the temperature information.

### CROSS-REFERENCE TO RELATED APPLICATION

This application is based upon and claims the benefit of priority of the prior Japanese Patent Application No. 2015-092495, filed on Apr. 30, 2015, the entire contents of which are incorporated herein by reference.

### FIELD

The embodiments discussed herein are related to a control method, an information processing system, and a storage medium.

### BACKGROUND

With the widespread use of data centers and on-premises cloud systems, the number of cases where multiple servers are arranged in each of racks and many servers are managed on a rack basis has been increasing. In such an information processing system, servers are installed in racks upon the shipment from a factory or are installed at a site such as a data center and connected to a network switch through cables.

However, in order to manage materials and ensure the convenience of maintenance, the IDs of the servers and the like are associated with the positions of the servers and the like in the racks and managed. The IDs are serial numbers of electronic devices such as the servers, MAC addresses used in an administration LAN, or the like and are information specific to each of the electronic devices such as the servers, for example.

Normally, the association of the IDs of the servers with the positions of the servers in the racks is executed by visually confirming the IDs of the servers and the positions in the racks and entering the IDs and the positions in a management ledger (for example, management software on a computer). However, if the IDs of the servers and the positions in the racks are manually associated, it takes great time and cost. Thus, techniques for automatically associating the IDs of servers with the positions of the servers in the racks have been researched.

For example, a technique for attaching modules for providing positional information to racks, attaching sensors for reading the positional information from the modules to servers, and automatically associating the servers with the positions of the servers in the racks has been developed. In addition, a technique for identifying servers and the positions of the servers in racks using an intelligent power distribution unit (PDU) has been developed.

Furthermore, a technique for using a temperature sensor to determine the position of a specific electronic device or the position of a hot spot in a processor has been developed (refer to, for example, Japanese Laid-open Patent Publication No. 7-152442 or Japanese Laid-open Patent Publication No. 2005-346590).

In the aforementioned technique for automatically associating servers with the positions of the servers in racks, special devices (the modules and the sensors, the intelligent PDU, or the like) are used and thus costly. In addition, a system in which the special devices are not able to be installed exists. Thus, it is desirable to automatically associate electronic devices with information identifying the electronic devices without the special devices.

### SUMMARY

According to an aspect of the invention, a control method executed by an information processing system that includes a plurality of electronic devices arranged side by side in a single direction in a common housing and having temperature sensors and includes a managing device coupled to the plurality of electronic devices, the control method includes activating an electronic device among the plurality of electronic devices based on a predetermined order; receiving temperature information from the temperature sensors included in the plurality of electronic devices, the temperature information indicating temperatures of the plurality of electronic devices that are measured when any of the plurality of electronic devices operates and another one or more electronic devices excluding the operating electronic device do not operate; and identifying positions of the plurality of electronic devices arranged in the common housing, based on amounts of changes in temperatures of the plurality of electronic devices calculated using the temperature information.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a schematic diagram illustrating an information processing system according to a first embodiment;

FIG. 2 is a top view of an operation server;

FIG. 3 is a schematic diagram illustrating a configuration of a managing device after dedicated software is read;

FIG. 4 is a first flowchart of a control method to be executed by the information processing system according to the first embodiment;

FIG. 5 is a second flowchart of the control method to be executed by the information processing system according to the first embodiment;

FIG. 6 is a third flowchart of the control method to be executed by the information processing system according to the first embodiment;

FIG. 7 is a diagram illustrating an example of a managed device information table;

FIG. 8 is a diagram illustrating the managed device information table in which 1 is recorded as a rack position number of an operation server arranged on a top shelf of a rack;

FIG. 9 is a diagram illustrating the managed device information table in which serial numbers of servers are recorded;

FIG. 10 is a diagram illustrating an example of a temperature management information table;

FIG. 11 is a diagram illustrating the temperature management information table when a server with a table identification number 1 operates;

FIG. 12 is a diagram illustrating the temperature management information table after a sub-process executed for the second time is terminated;

FIG. 13 is a diagram illustrating an example of a temperature change table;

FIG. 14 is a diagram illustrating the managed device information table after rack position numbers of all the servers are recorded;

FIG. 15 is a schematic diagram illustrating an information processing system according to a second embodiment;

FIG. 16 is a first flowchart of a control method to be executed by the information processing system according to the second embodiment;

FIG. 17 is a second flowchart of the control method to be executed by the information processing system according to the second embodiment;

FIG. 18 is a third flowchart of the control method to be executed by the information processing system according to the second embodiment;

FIG. 19 is a diagram illustrating an example of a managed device information table;

FIG. 20 is a diagram illustrating the managed device information table in which serial numbers of servers are recorded;

FIG. 21 is a diagram illustrating an example of a temperature management information table;

FIG. 22 is a diagram illustrating the temperature management information table when a server with a table identification number 2 operates;

FIG. 23 is a diagram illustrating the temperature management information table after a sub-process executed for the second time is terminated;

FIG. 24 is a diagram illustrating an example of a temperature change table;

FIG. 25 is a diagram illustrating the managed device information table after rack position numbers of all the servers are recorded;

FIG. 26 is a schematic diagram illustrating an information processing system according to a third embodiment;

FIG. 27 is a first flowchart of a control method to be executed by the information processing system according to the third embodiment;

FIG. 28 is a second flowchart of the control method to be executed by the information processing system according to the third embodiment;

FIG. 29 is a third flowchart of the control method to be executed by the information processing system according to the third embodiment;

FIG. 30 is a diagram illustrating an example of a managed device information table;

FIG. 31 is a diagram illustrating the managed device information table in which the serial numbers of servers are recorded;

FIG. 32 is a diagram illustrating an example of a temperature management information table;

FIG. 33 is a diagram illustrating the temperature management information table when the server with the table identification number 2 operates;

FIG. 34 is a diagram illustrating the temperature management information table after a sub-process executed for the second time is terminated;

FIG. 35 is a diagram illustrating an example of a temperature change table;

FIG. 36 is a diagram illustrating the managed device information table after rack position numbers of all the servers are recorded;

FIG. 37 is a schematic diagram illustrating an information processing system according to a fourth embodiment;

FIG. 38 is a first flowchart of a control method to be executed by the information processing system according to the fourth embodiment;

FIG. 39 is a second flowchart of the control method to be executed by the information processing system according to the fourth embodiment;

FIG. 40 is a third flowchart of the control method to be executed by the information processing system according to the fourth embodiment;

FIG. 41 is a fourth flowchart of the control method to be executed by the information processing system according to the fourth embodiment;

FIG. 42 is a diagram illustrating a managed device information table;

FIG. 43 is a diagram illustrating the managed device information table in which 1 is recorded as a rack position number of an operation server arranged on a top shelf of a rack;

FIG. 44 is a diagram illustrating an example of a temperature management information table;

FIG. 45 is a diagram illustrating the temperature management information table when the server with the table identification number 2 operates;

FIG. 46 is a diagram illustrating the temperature management information table after a sub-process executed for the second time is terminated;

FIG. 47 is a diagram illustrating an example of a temperature change table;

FIG. 48 is a diagram illustrating the managed device information table after rack position numbers of all electronic devices are recorded;

FIG. 49 is a schematic diagram illustrating an information processing system according to a fifth embodiment;

FIG. 50 is a first flowchart of a control method to be executed by the information processing system according to the fifth embodiment;

FIG. 51 is a second flowchart of the control method to be executed by the information processing system according to the fifth embodiment;

FIG. 52 is a third flowchart of the control method to be executed by the information processing system according to the fifth embodiment;

FIG. 53 is a diagram illustrating an example of a managed device information table;

FIG. 54 is a diagram illustrating the managed device information table in which 1 is recorded as a rack position number of an operation server arranged on the leftmost side of a rack;

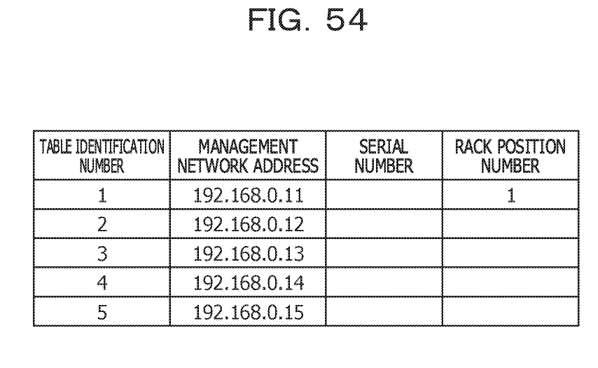

FIG. 55 is a diagram illustrating the managed device information table in which serial numbers of servers are recorded;

FIG. 56 is a diagram illustrating an example of a temperature management information table;

FIG. 57 is a diagram illustrating the temperature management information table when the server with the table identification number 1 operates;

FIG. 58 is a diagram illustrating the temperature management information table after a sub-process executed for the second time is terminated;

FIG. 59 is a diagram illustrating an example of a temperature change table; and

FIG. 60 is a diagram illustrating the managed device information table after rack position numbers of all the servers are described.

### DESCRIPTION OF EMBODIMENTS

Hereinafter, embodiments are described with reference to the accompanying drawings.

### First Embodiment

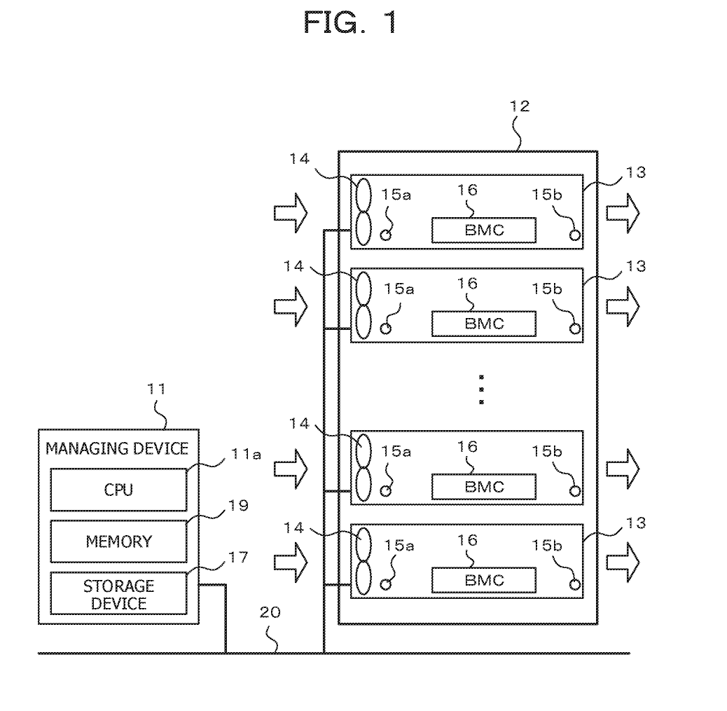

FIG. 1 is a schematic diagram illustrating an information processing system according to a first embodiment.

The information processing system according to the first embodiment includes a managing device 11 and multiple operation servers 13 (hereinafter also merely referred to as “servers”) arranged in racks 12. The managing device 11 and the operation servers 13 are connected to each other through a network 20.

Although FIG. 1 illustrates a single rack 12, the multiple racks 12 are included in the information processing system according to the first embodiment. In each of the racks 12, multiple operation servers 13 are arranged. The managing device 11 is connected to the servers 13 through the network 20.

The operation servers 13 are an example of electronic devices. Each of the racks 12 is an example of a housing. In FIG. 1, the managing device 11 is arranged outside the rack 12. The managing device 11, however, may be arranged in the rack 12. A specific operation server 13 arranged in the rack 12 may be used as the managing device 11.

The operation servers 13 have fans 14 for absorbing air within a room and cooling electronic parts (central processing units (CPUs) and the like) within the servers 13. White arrows illustrated in FIG. 1 indicate directions in which the air flows by the fans 14.

Hereinafter, surfaces of the racks 12 from which the air is absorbed into the racks 12 are referred to as absorption surfaces, while surfaces of the racks 12 from which the air is discharged from the racks 12 is referred to as discharge surfaces. The air that cools the electronic parts within the servers 13 and thereby increases in temperature is discharged from the discharge surfaces of the racks 12 to the outside of the racks 12.

FIG. 1 illustrates an example in which the fans 14 are arranged in housings of the servers 13. The fans 14, however, may be arranged outside the housings of the servers 13.

The servers 13 have temperature sensors 15a and temperature sensors 15b. The temperature sensors 15a are arranged on the sides of the absorption surfaces of the racks 12 and configured to detect temperatures of the air that has flowed into the racks 12, while the temperature sensors 15b are arranged on the sides of the discharge surfaces of the racks 12 and configured to detect temperatures of the servers 13.

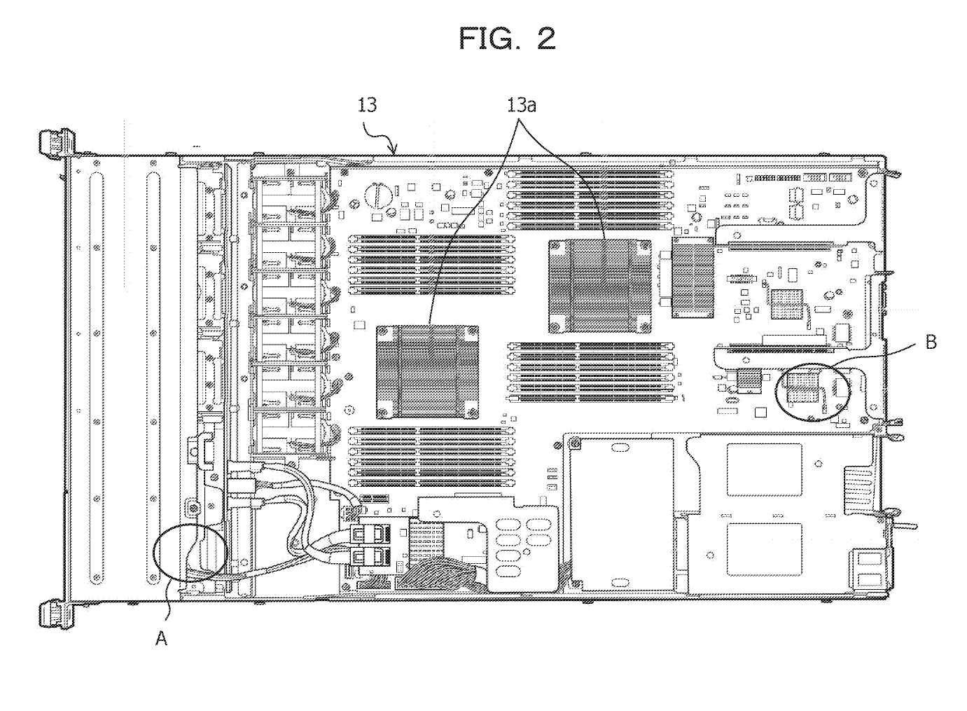

FIG. 2 is a top view of an operation server 13. In each of the operation servers 13, the temperature sensor 15a is arranged at a position indicated by an ellipse A, and the temperature sensor 15b is arranged at a position indicated by an ellipse B, for example.

In general servers, the temperature sensors 15a and 15b and base management controllers (BMCs) 16 are mounted as standard. The general servers may transmit information indicating temperatures of air on the sides of absorption and temperatures of the general servers to an external device through the BMCs 16. The external device may control the fans 14 of the general servers through the BMCs 16, turn on power sources of the general servers through the BMCs 16, and turn off the power sources of the general servers through the BMCs 16.

In the first embodiment, the aforementioned general servers are used as the operation servers 13, while temperature sensors 15a and 15b and BMCs 16 are not additionally prepared. A symbol 13a illustrated in FIG. 2 indicates CPUs (heat generating parts) installed in the server 13.

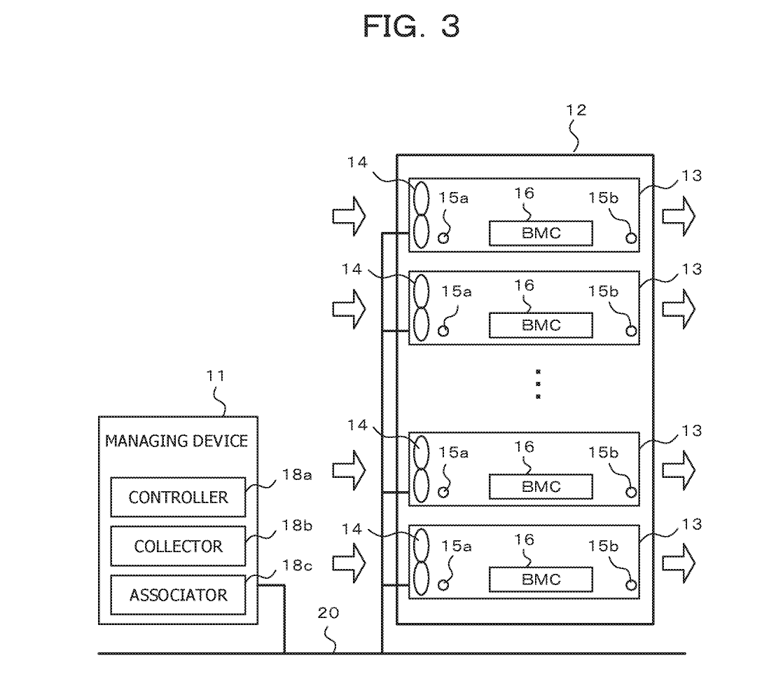

The managing device 11 is a computer and includes a CPU 11a, a storage device 17, and a memory 19, as illustrated in FIG. 1. Dedicated software is stored in the storage device 17. As illustrated in FIG. 3, the managing device 11 includes a controller 18a, a collector 18b, and an associator 18c. These functional blocks included in the managing device 11 are achieved by reading the software.

As described later, the collector 18b collects temperature information of the servers 13 from the temperature sensors 15a and 15b. The associator 18c associates the servers 13 with identification information (the positions of the servers in the racks 12 in the following example) specific to the servers 13 based on changes in the temperature information collected by the collector 18b. The controller 18a controls operations of the servers 13 and executes processes in accordance with set procedures.

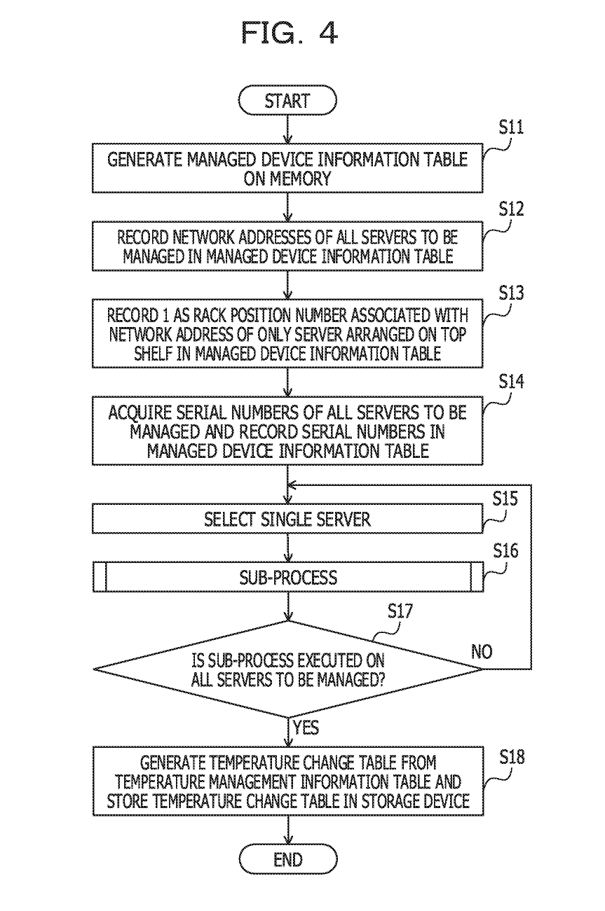

FIGS. 4, 5, and 6 are flowcharts of a control method to be executed by the information processing system according to the first embodiment.

In the first embodiment, specific management network addresses are set in the operation servers 13 by a network administrator in advance, respectively. Specific serial numbers (IDs) are set in the operation servers 13 by a manufacturer in advance, respectively. The managing device 11 may acquire the serial numbers from the operation servers 13 through the BMCs 16. In addition, management network addresses of operation servers 13 arranged on top shelves (uppermost shelves) of the racks 12 are identified in advance.

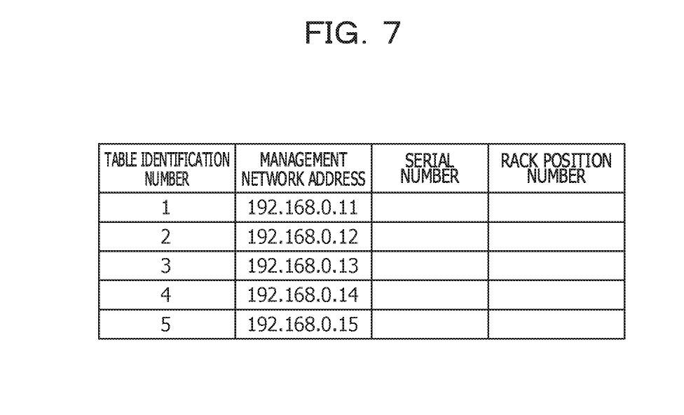

First, in S11, the managing device 11 (controller 18a) generates a managed device information table on the memory 19. The managed device information table has a table identification number item, a management network address item, a serial number item, and a rack position number item, as illustrated in FIG. 7, for example. FIG. 7 illustrates an example in which five operation servers 13 are arranged in a rack 12.

Next, a process illustrated in FIG. 4 proceeds to S12 and the managing device 11 (collector 18b) accesses, through the network 20, all servers 13 to be managed and acquires management network addresses of the servers 13. Then, the managing device 11 (collector 18b) records the acquired management network addresses in the managed device information table, as illustrated in FIG. 7.

In the example illustrated in FIG. 7, table identification numbers are given to the operation servers 13 with the detected management network addresses in the order of the management network addresses.

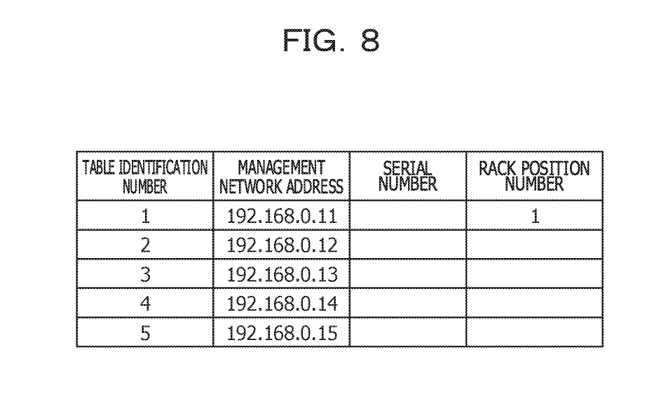

Next, the process proceeds to S13 and the managing device 11 (controller 18a) records 1 as a rack position number of an operation server 13 arranged on the top shelf (uppermost shelf) of the rack 12, as illustrated in FIG. 8.

The rack position number 1 indicates that the operation server 13 is arranged on the top shelf of the rack 12. As described above, the management network address of the operation server 13 arranged on the top shelf of the rack 12 is identified in advance. In this example, the operation server 13 with a management network address “192.168.0.11” is arranged on the top shelf of the rack 12.

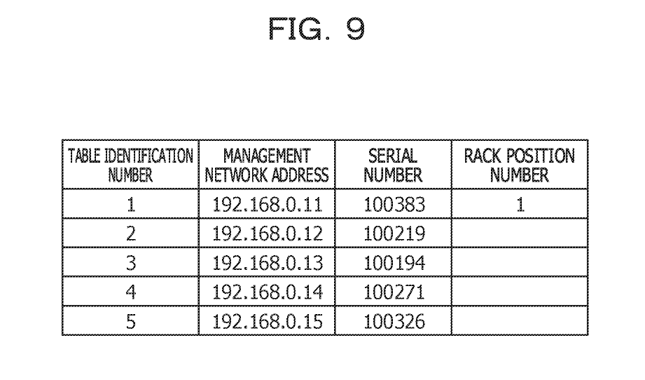

Next, the process proceeds to S14 and the managing device 11 (collector 18b) accesses the operation servers 13 through the network 20 and acquires serial numbers (IDs) of the servers 13. Then, the managing device 11 (collector 18b) associates the serial numbers of the servers 13 with the table identification numbers and the management network addresses and records the serial numbers of the servers 13 in the managed device information table, as illustrated in FIG. 9.

Next, the process proceeds to S15 and the managing device 11 (controller 18a) selects a single server 13 from among the servers 13 to be managed. In this case, the managing device 11 selects the servers 13 in the order of the management network addresses. Thus, the server 13 with the management network address “192.168.0.11” (table identification number 1) is selected first. The order in which the servers 13 are selected, however, is not limited to this.

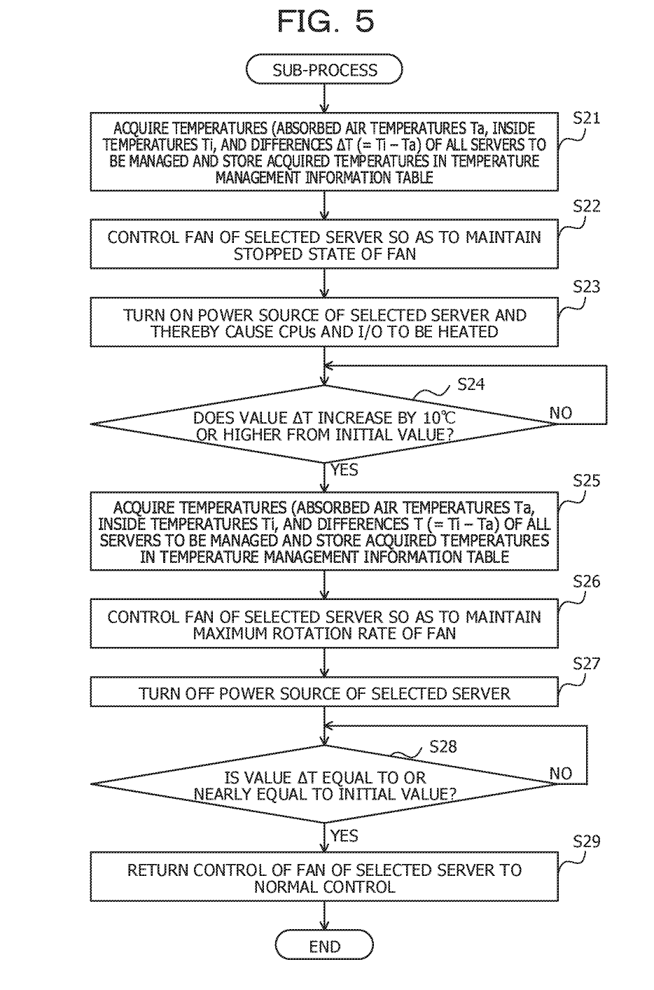

After that, the process proceeds to S16 and the managing device 11 executes a sub-process. The sub-process is described below with reference to FIG. 5.

In S21, the managing device 11 (collector 18b) accesses, through the network 20, all the servers to be managed and acquires absorbed air temperatures Ta and inside temperatures Ti of the servers 13. The absorbed air temperatures Ta are detected by the temperature sensors 15a, while the inside temperatures Ti are detected by the temperature sensors 15b.

Subsequently, the managing device 11 (controller 18a) calculates the differences ΔT (=Ti−Ta) between the inside temperatures Ti and the absorbed air temperatures Ta for the operation servers 13 and generates a temperature management information table on the memory 19.

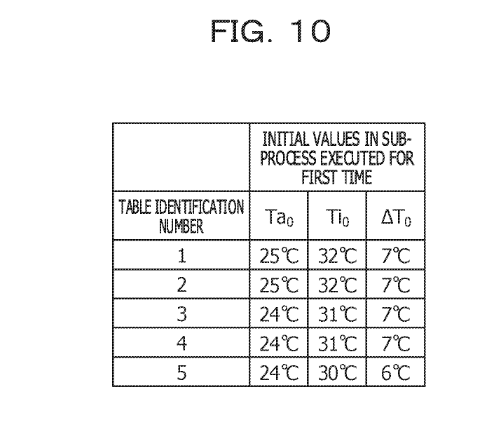

FIG. 10 is a diagram illustrating an example of the temperature management information table. In FIG. 10, indices 0 for Ta, Ti, and ΔT indicate values (initial values) measured in the sub-process executed for the first time.

As illustrated in FIG. 10, in the temperature management information table, the absorbed air temperatures Ta and inside temperatures Ti of the servers 13 and the differences ΔT between the inside temperatures Ti and the absorbed air temperatures Ta are recorded for the table identification numbers.

Next, the sub-process proceeds to S22 and the managing device 11 (controller 18a) stops the fan 14 of the selected server 13 (server with the table identification number 1 in the sub-process executed for the first time) through the network 20 and the BMC 16 of the selected server 13.

In this case, the fan 14 may not be stopped. However, in order to reduce a time period for which the inside temperature Ti increases upon an operation of the server 13 in the next process, the fan 14 is stopped in S22 in the first embodiment. In order to further reduce the time period for which the inside temperature Ti increases, a specific program may be executed and apply a load to the CPUs included in the server 13.

Next, the sub-process proceeds to S23 and the managing device 11 (controller 18a) turns on a power source of the selected server 13 through the network 20 and the BMC 16 of the selected server 13 and thereby causes the server 13 to operate. Due to the operation of the server 13, the CPUs and I/O (input/output) of the server 13 are heated and the temperature Ti of the server 13 increases. The CPUs and the I/O are examples of heat generating parts.

Next, the sub-process proceeds to S24 and the managing device 11 (controller 18a) stands by (looping) until the difference ΔT of the selected server 13 increases by a predetermined temperature (of 10° C. in this example) or higher from an initial value of the difference ΔT. Then, when the difference ΔT of the selected server 13 increases by the predetermined temperature or higher from the initial value, the sub-process proceeds to S25.

In S25, the managing device 11 (controller 18a) accesses, through the network 20, all the servers 13 to be managed and acquires the absorbed air temperatures Ta and inside temperatures Ti of the servers 13. The managing device 11 (controller 18a) calculates the differences ΔT between the absorbed air temperatures Ta and inside temperatures Ti of all the servers 13 to be managed. Then, the managing device 11 (controller 18a) stores the absorbed air temperatures Ta, the inside temperatures Ti, and the differences ΔT in the temperature management information table.

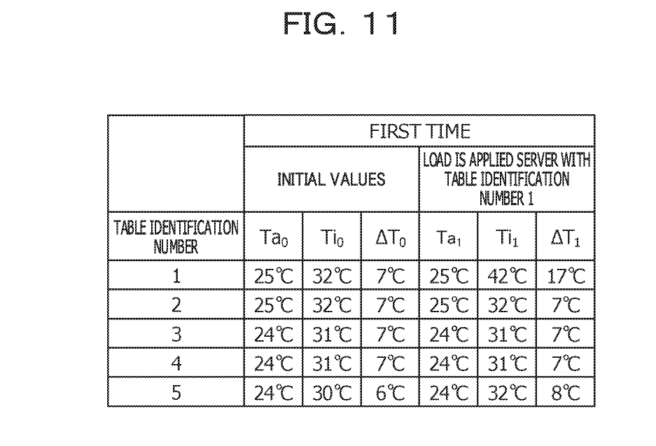

FIG. 11 illustrates the temperature management information table in which absorbed air temperatures Ta₁, inside temperatures Ti₁, and the differences ΔT₁ between the absorbed air temperatures Ta₁ and the inside temperatures Ti₁ when the server 13 with the table identification number 1 operates are recorded.

Next, the sub-process proceeds to S26 and the managing device 11 (controller 18a) controls a rotation rate of the fan 14 of the selected server 13 so as to set the rotation rate of the fan 14 to the maximum rotation rate through the network 20 and the BMC 16 of the selected server 13. In S27, the managing device 11 (controller 18a) turns off the power source of the selected server 13.

The rotation rate of the fan 14 is set to the maximum rotation rate in S26 in order to reduce a time period for which the inside temperature Ti of the server 13 is reduced to an initial value (or the inside temperature Ti before the power source is turned on). In S27, the server 13 may become a sleep state or an idle state, instead of the turning-off of the power source of the server 13.

Next, the sub-process proceeds to S28 and the managing device 11 (controller 18a) stands by (looping) until the difference ΔT of the server 13 that operates in S23 becomes equal to or nearly equal to the initial value (or the difference ΔT before the server 13 operates). When the difference ΔT of the operating server 13 becomes equal to or nearly equal to the initial value, the sub-process proceeds to S29 and the managing device 11 (controller 18a) returns control of the fan 14 of the server 13 to normal control (so that the rotation rate of the fan 14 is based on the inside temperature Ti, for example). Then, the managing device 11 terminates the sub-process and causes the process to proceed to S17 illustrated in FIG. 4.

In S52, the managing device 11 (controller 18a) determines whether or not the sub-process was executed on all the servers 13 to be managed. If the managing device 11 (controller 18a) determines that the sub-process is yet to be executed on at least any of all the servers 13 to be managed (No in S17), the process returns to S15 and the managing device 11 (controller 18a) selects a next server 13 among servers 13 that are yet to be subjected to the sub-process. After that, in S16, the sub-process (of S21 to S29) illustrated in FIG. 5 is executed on the selected server 13.

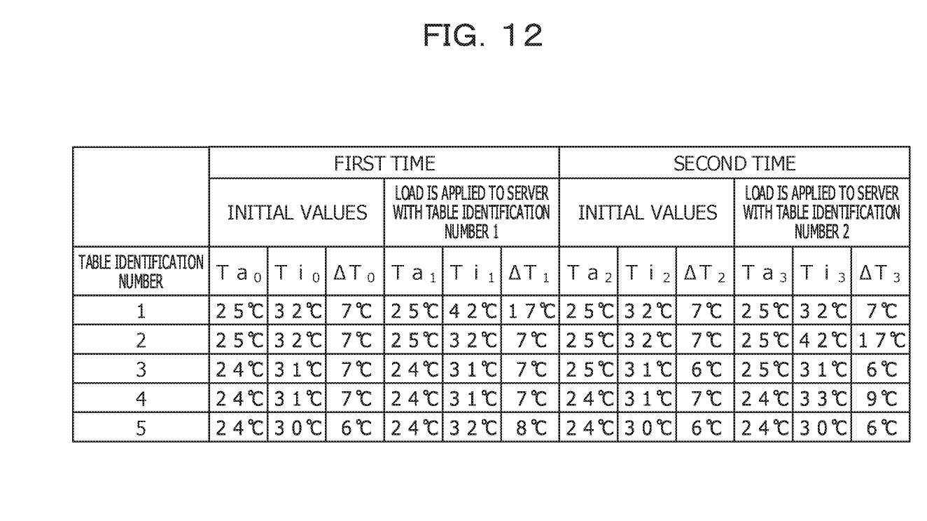

FIG. 12 illustrates initial values of absorbed air temperatures Ta and inside temperatures Ti obtained in the sub-process executed for the first and second times, the differences ΔT between the initial values of the temperatures Ta and Ti obtained in the sub-process executed for the first and second times, values of absorbed air temperatures Ta and inside temperatures Ti obtained when specific servers (servers selected in S15) operate, and the differences ΔT between the temperatures Ta and Ti obtained when the specific servers operate.

As illustrated in FIG. 12, initial values of absorbed air temperatures Ta, initial values of inside temperatures Ti, the differences ΔT between the initial values of the temperatures Ta and Ti, values of absorbed air temperatures Ta and inside temperatures Ti when a server operates, and the differences ΔT between the temperatures Ta and Ti when the server operates, are recorded in the temperature management information table for each execution of the sub-process.

If the managing device 11 (controller 18a) determines that the sub-process was executed on all the servers 13 to be managed (Yes in S17), the process proceeds to S18. Then, the managing device 11 (controller 18a) generates a temperature change table from the temperature management information table and stores the generated temperature change table in the storage device 17.

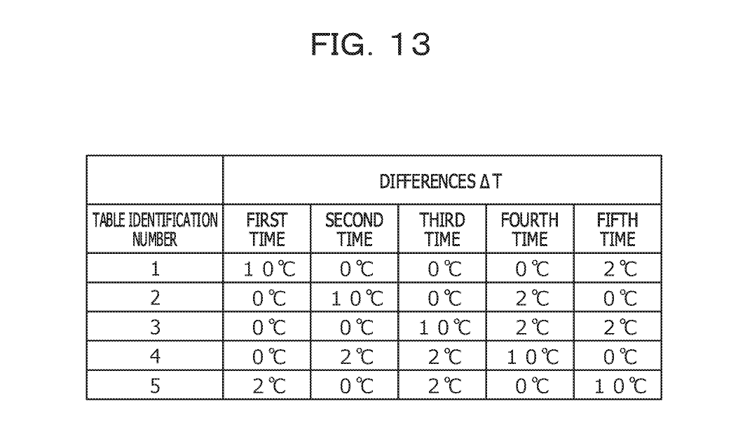

FIG. 13 is a diagram illustrating an example of the temperature change table. As illustrated in FIG. 13, in the temperature change table, the differences ΔT between the absorbed air temperatures Ta and inside temperatures Ti of all the servers 13 when a specific server (server selected in S15) operates are recorded for each execution of the sub-process.

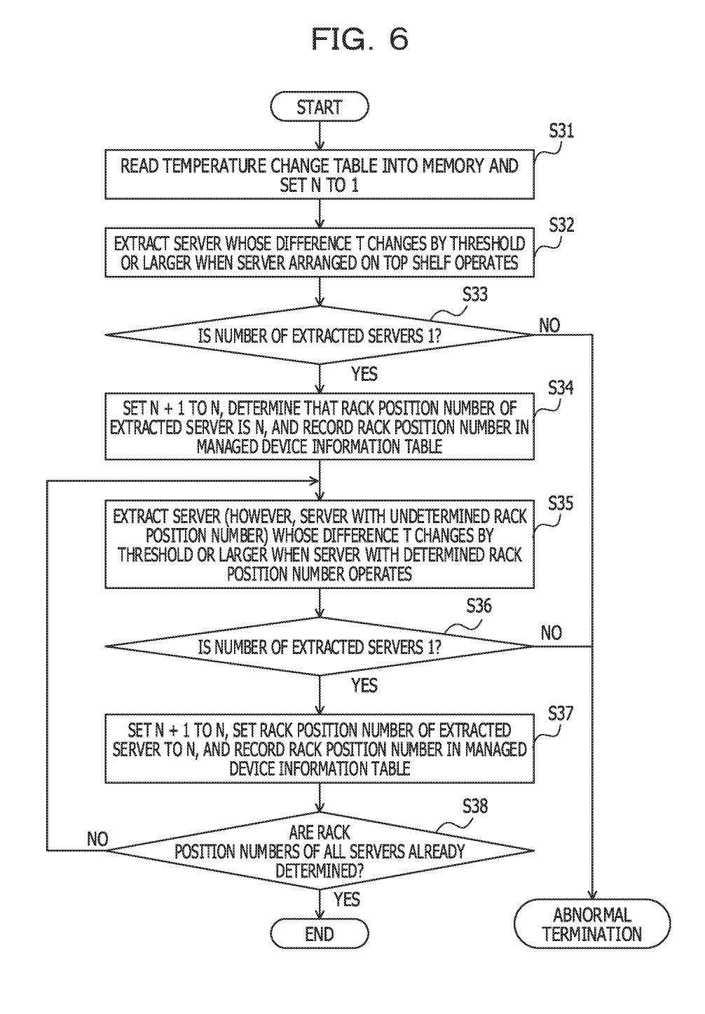

When generating the temperature change table, the managing device 11 starts a process indicated by the flowchart of FIG. 6.

In S31, the managing device 11 (associator 18c) reads the temperature change table into the memory 19 from the storage device 17 and sets a variable N to 1 (N→1).

Next, the process proceeds to S32 and the managing device 11 (associator 18c) references the temperature change table and extracts a server whose difference ΔT changes by a threshold or larger when the server arranged on the top shelf of the rack 12 operates.

In the first embodiment, the threshold is set to a value slightly lower than 2° C. The temperature change table illustrated in FIG. 13 indicates that the difference ΔT between an absorbed air temperature Ta and inside temperature Ti of a server with a table identification number 5 changes by the threshold or larger when the server with the table identification number 1 operates. Thus, the managing device 11 (associator 18c) extracts the server with the table identification number 5.

Next, the process proceeds to S33 and the managing device 11 (associator 18c) determines whether or not the number of extracted servers is 1. If the number of extracted servers is 1 (Yes in S33), the process proceeds to S34. If the number of extracted servers is 0 or 2 or larger (No in S33), the managing device 11 assumes that an abnormality occurred for some reason and the managing device 11 terminates the process (abnormal termination).

If the process proceeds from S33 to S34, the managing device 11 (associator 18c) newly sets a value obtained by adding 1 to N to N (N+1→N). Then, the managing device 11 (associator 18c) determines that a rack position number of the server extracted in S32 is N and the managing device 11 (associator 18c) records the determined rack position number in the managed device information table.

Since the initial value of N is 1 as described above, the variable N becomes 2 in S34. Thus, the rack position number of the server 13 extracted in S32 and having the table identification number 5 is “2”. Specifically, the server 13 with the table identification number 5 is determined as a server arranged on the second top shelf of the rack 12.

Next, the process proceeds to S35 and the managing device 11 (associator 18c) extracts a server (however, a server with an undetermined rack position number) whose difference ΔT changes by the threshold or larger when the server 13 with the rack position number determined in S34 operates.

The temperature management information table illustrated in FIG. 13 indicates that the differences ΔT of the servers with the table identification numbers 1 and 3 when the server with the table identification number 5 operates change by the threshold or larger. Since the rack position number of the server with the table identification number 1 is already determined to be “1”, the server with the table identification number 3 is extracted in S35.

Next, the process proceeds to S36 and the managing device 11 (associator 18c) determines whether or not the number of extracted servers is 1. If the number of extracted servers is 1 (Yes in S36), the process proceeds to S37. If the number of extracted servers is 0 or 2 or larger (No in S36), the managing device 11 assumes that an abnormality occurred for some reason and the managing device 11 terminates the process (abnormal termination).

If the process proceeds from S36 to S37, the managing device 11 newly sets a value obtained by adding 1 to N to N (N+1→N). Then, the managing device 11 sets, to N, a rack position number of the server extracted in S35 and records the rack position number in the managed device information table.

Since the variable N becomes 2 in S34, the variable N becomes 3 in S37. Thus, the rack position number of the server with the table identification number 3 is “3”. Specifically, the server 13 with the table identification number 3 is determined as a server arranged on the third top shelf of the rack 12.

Next, the process proceeds to S38 and the managing device 11 (associator 18c) determines whether or not rack position numbers of all the servers 13 were determined. If the managing device 11 (associator 18c) determines that a rack position number of at least any of all the servers 13 is yet to be determined (No in S38), the process returns to S35 and the managing device 11 (associator 18c) extracts a next server and determines a rack position number of the extracted server in S37.

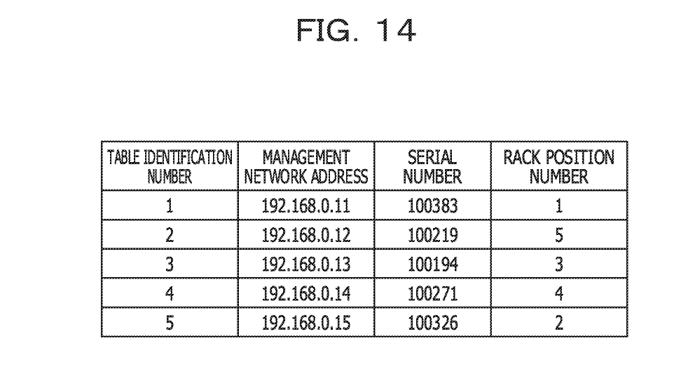

By repeating a loop of S35 to S38 in the aforementioned manner, the rack position numbers of all the servers 13 to be managed are determined and recorded in the managed device information table. FIG. 14 illustrates the managed device information table after the rack position numbers of all the servers 13 are recorded.

If the managing device 11 (associator 18c) determines that the rack position numbers of all the servers 13 were determined (Yes in S38), the managing device 11 terminates the process (normal termination).

In the first embodiment, the temperature sensors 15a and 15b and BMCs 16 that are mounted as standard in the servers 13 are used, and the operation servers 13 are automatically associated with the positions of the operation servers 13 in the racks 12. In the first embodiment, a module storing positional information and a sensor for acquiring the positional information are not used or a specific device such as a PDU is not used, and thus effects of improving general versatility and causing installation cost to be relatively low are obtained.

The effects depend on the performance of the managing device 11, the performance of the servers 13, and the like. In the first embodiment, however, it takes about 6 minutes (excluding a time period for activation caused by turning-on of a power source) to determine the position of each server 13. Processes of determining the positions of electronic devices (servers 13 and the like) arranged in the racks 12 may be executed in parallel.

The first embodiment describes the case where the management network addresses of the servers 13 arranged on the top shelves (uppermost shelves) of the racks 12 are identified in advance. The techniques disclosed herein, however, are applicable to a case where management network addresses of servers 13 arranged on bottom shelves (lowermost shelves) of the racks 12 are identified in advance. In this case, rack position numbers of the servers 13 are determined in descending order, like a third embodiment described later.

The first embodiment describes the case where the electronic devices are the operation servers. The electronic devices are not limited to the operation servers. A part or all of the electronic devices may be storage devices, switch devices, or the like.

### Second Embodiment

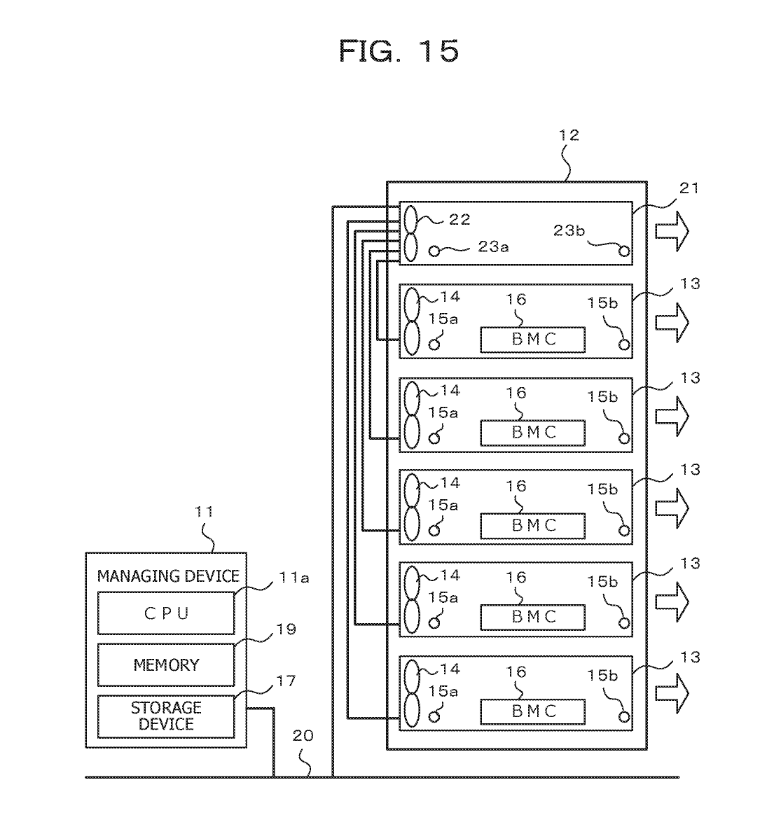

FIG. 15 is a schematic diagram illustrating an information processing system according to a second embodiment. In FIG. 15, parts that are the same as those illustrated in FIG. 1 are indicated by the same reference numbers and symbols as those illustrated in FIG. 1.

In the second embodiment, a network switch 21 is arranged on the top shelf (uppermost shelf) of a rack 12, as illustrated in FIG. 15. The operation servers 13 are arranged on the second to sixth shelves of the rack 12.

The managing device 11 is connected to the operation servers 13 through the network switch 21. The network switch 21 includes a fan 22, a temperature sensor 23a for detecting a temperature on the side of air absorption, and a temperature sensor 23b for detecting temperatures of the servers 13.

Hereinafter, the network switch 21 and the operation servers 13 are collectively referred to as electronic devices.

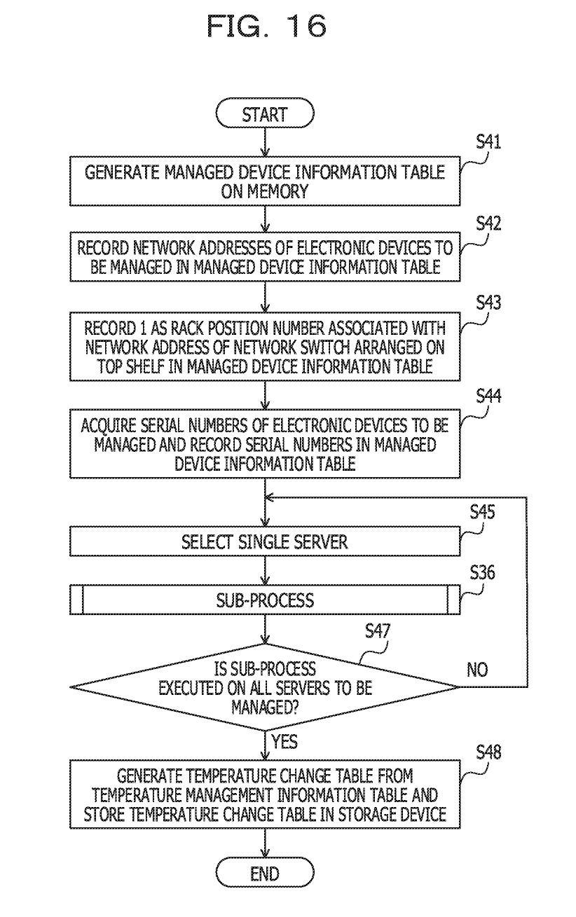

FIGS. 16, 17, and 18 are flowcharts of a control method to be executed by the information processing system according to the second embodiment.

In the second embodiment, specific management network addresses are set in the electronic devices (network switch 21 and servers 13) by a network administrator in advance, respectively. Specific serial numbers (IDs) are set in the electronic devices by a manufacturer in advance, respectively. The managing device 11 may access the electronic devices and acquire the serial numbers from the electronic devices.

In addition, the network switch 21 is identified to be arranged on the top shelf of the rack 12 and the management network address of the network switch 21 is identified. It is assumed that the management network address of the network switch 21 is “192.168.0.1”.

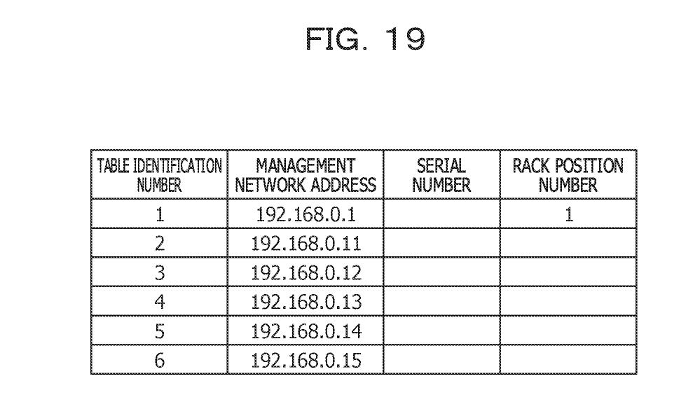

In S41, the managing device 11 generates a managed device information table on the memory 19. The managed device information table has a table identification number item, a management network address item, a serial number item, and a rack position number item, as illustrated in FIG. 19, for example.

Next, a process illustrated in FIG. 16 proceeds to S42 and the managing device 11 accesses the electronic devices (network switch 21 and operation servers 13) through the network 20 and acquires management network addresses of the electronic devices. Then, the managing device 11 records the acquired management network addresses in the managed device information table, as illustrated in FIG. 19.

In the example illustrated in FIG. 19, a table identification number of the network switch 21 is 1. Table identification numbers 2 to 6 are given to the operation servers 13 with the detected management network addresses in the order of the management network addresses.

Next, the process proceeds to S43 and the managing device 11 records 1 as a rack position number of the network switch 21 arranged on the top shelf of the rack 12.

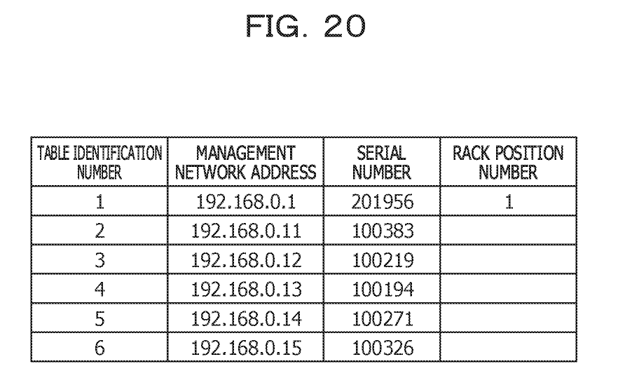

Next, the process proceeds to S44 and the managing device 11 accesses the electronic devices (network switch 21 and operation servers 13) through the network 20 and acquires the serial numbers (IDs) of the electronic devices. Then, the managing device 11 associates the serial numbers of the electronic devices with the table identification numbers and the management network addresses and records the serial numbers in the managed device information table, as illustrated in FIG. 20.

Next, the process proceeds to S45 and the managing device 11 selects a single server 13 among the servers 13 to be managed. The managing device 11 selects the servers 13 in the order of the management network addresses. Thus, the server 13 with the management network address “192.168.0.11” (table identification number 2) is selected first.

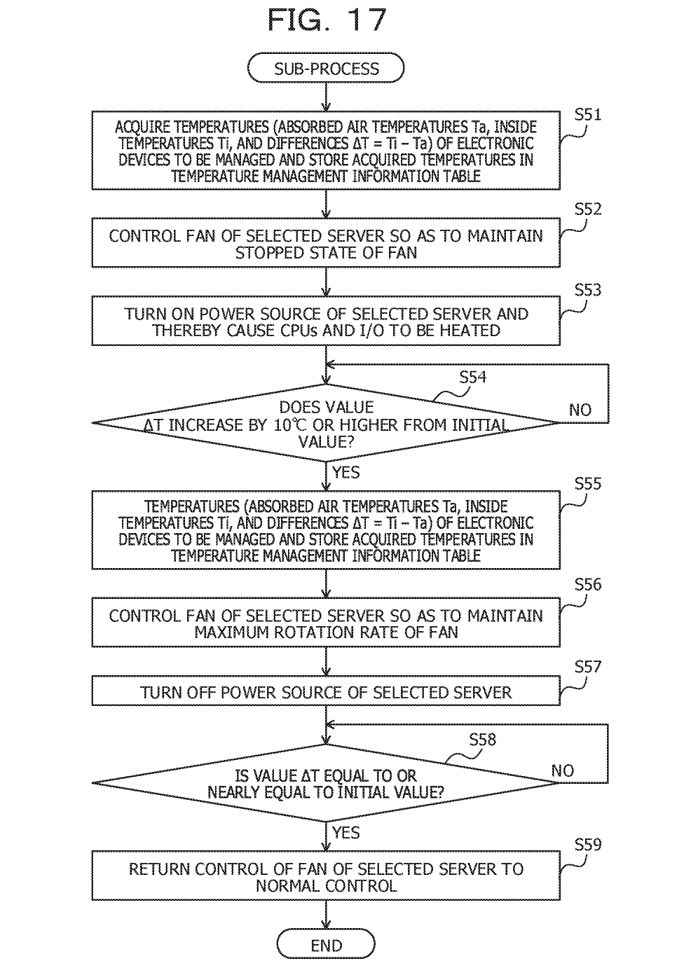

After that, the process proceeds to S46 and the managing device 11 executes a sub-process. The sub-process is described below with reference to FIG. 17.

In S51, the managing device 11 accesses, through the network 20, the electronic devices (network switch 21 and operation servers 13) and acquires absorbed air temperatures Ta and inside temperatures Ti of the electronic devices.

Subsequently, the managing device 11 calculates the differences ΔT (=Ti−Ta) between the inside temperatures Ti and the absorbed air temperatures Ta for the electronic devices and generates a temperature management information table on the memory 19.

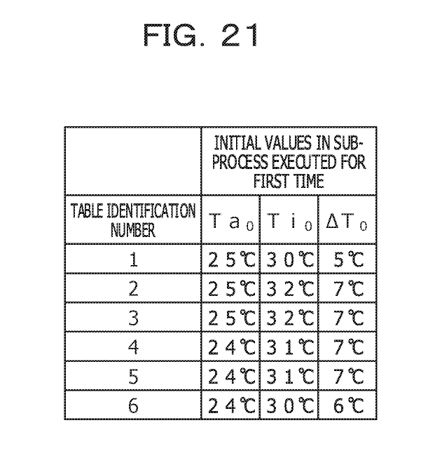

FIG. 21 is a diagram illustrating an example of the temperature management information table. As illustrated in FIG. 21, in the temperature management information table, the absorbed air temperatures Ta and inside temperatures Ti of the electronic devices (network switch 21 and operation servers 13) and the differences ΔT between the absorbed air temperatures Ta and the inside temperatures Ti are recorded.

Next, the process proceeds to S52 and the managing device 11 stops the fan 14 of the selected server 13 (server with the table identification number 2 in the sub-process executed for the first time) through the network 20 and the BMC 16 of the selected server 13.

Next, the process proceeds to S53 and the managing device 11 turns on a power source of the selected server 13 through the network 20 and the BMC 16 of the selected server 13 and thereby causes the server 13 to operate. Due to the operation of the server 13, the CPUs and I/O of the server 13 are heated and the inside temperature Ti of the server 13 increases.

Next, the process proceeds to S54 and the managing device 11 stands by (looping) until the difference ΔT of the selected server 13 increases by a predetermined temperature (of 10° C. in this example) or higher from an initial value of the difference ΔT. When the difference ΔT of the selected server 13 increases by the predetermined temperature or higher from the initial value, the process proceeds to S55.

In S55, the managing device 11 accesses, through the network 20, the electronic devices (network switch 21 and operation servers 13) to be managed and acquires the absorbed air temperatures Ta and inside temperatures Ti of the electronic devices. The managing device 11 calculates the differences ΔT between the absorbed air temperatures Ta and inside temperatures Ti of the electronic devices. Then, the managing device 11 stores the absorbed air temperatures Ta, the inside temperatures Ti, and the differences ΔT in the temperature management information table.

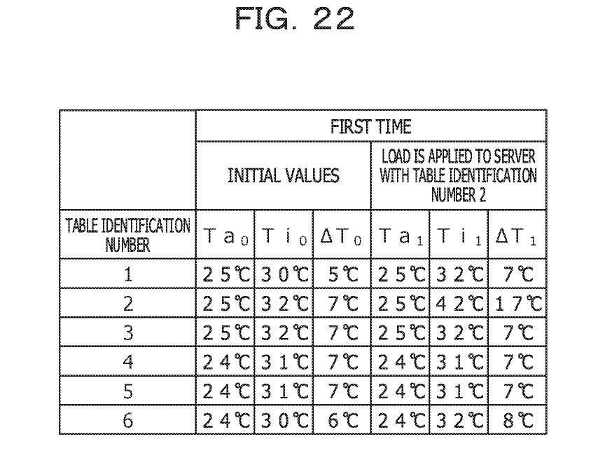

FIG. 22 illustrates the temperature management information table in which absorbed air temperatures Ta₁, inside temperatures Ti₁, and the differences ΔT₁ between the absorbed air temperatures Ta₁ and the inside temperatures Ti₁ when the server 13 with the table identification number 2 operates are recorded.

Next, the process proceeds to S56 and the managing device 11 controls a rotation rate of the fan 14 of the selected server 13 so as to set the rotation rate to the maximum rotation rate through the network 20 and the BMC 16 of the selected server 13. In S57, the managing device 11 turns off the power source of the server 13.

Next, the process proceeds to S58 and the managing device 11 stands by (looping) until the difference ΔT of the server 13 whose power source is turned on in S53 becomes equal to or nearly equal to the initial value (or the difference ΔT before the server 13 operates). When the difference ΔT of the server 13 whose power source is turned on becomes equal to or nearly equal to the initial value, the process proceeds to S59 and the managing device 11 returns control of the fan 14 of the server 13 to normal control (so that the rotation rate of the fan 14 is based on the inside temperature Ti, for example). Then, the managing device 11 terminates the sub-process and causes the process to proceed to S47 of the flowchart illustrated in FIG. 16.

In S47, the managing device 11 determines whether or not the sub-process was executed on all the servers 13 to be managed. If the managing device 11 determines that the sub-process is yet to be executed on at least any of all the servers 13 to be managed (No in S47), the process returns to S45 and the managing device 11 selects a next server 13 among servers 13 that are yet to be subjected to the sub-process. After that, in S46, the managing device 11 executes the sub-process (of S51 to S59) illustrated in FIG. 17.

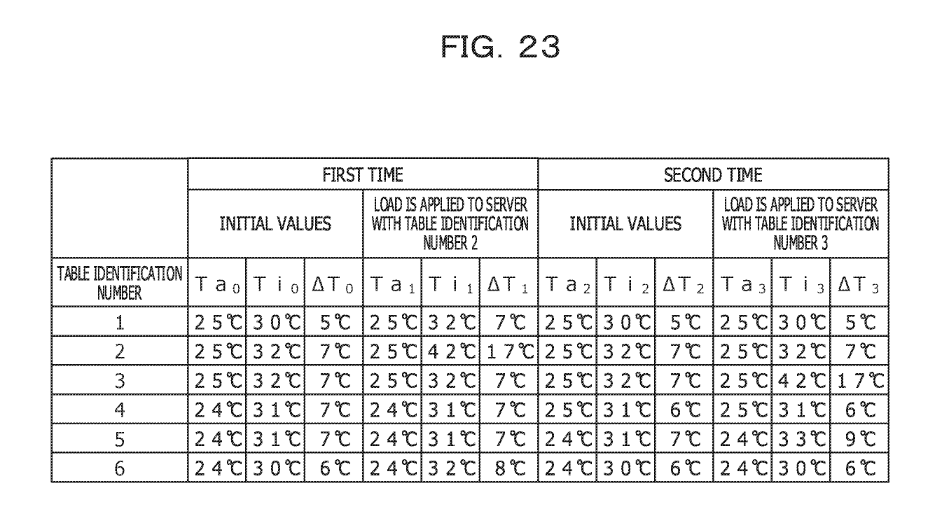

FIG. 23 illustrates initial values of absorbed air temperatures Ta and inside temperatures Ti obtained in the sub-process executed for the first and second times, the differences ΔT between the initial values of the temperatures Ta and Ti obtained in the sub-process executed for the first and second times, values of absorbed air temperatures Ta and inside temperatures Ti obtained when specific servers (servers selected in S45) operate, and the differences ΔT between the temperatures Ta and Ti obtained when the specific servers operate.

As illustrated in FIG. 23, initial values of absorbed air temperatures Ta, initial values of inside temperatures Ti, the differences ΔT between the initial values of the temperatures Ta and Ti, values of absorbed air temperatures Ta and inside temperatures Ti when a server operates, and the differences ΔT between the temperatures Ta and Ti when the server operates, are recorded in the temperature management information table for each execution of the sub-process.

If the managing device 11 determines whether or not the sub-process was executed on all the servers 13 to be managed (Yes in S47), the process proceeds to S48. Then, the managing device 11 generates a temperature change table from the temperature management information table and stores the generated temperature change table in the storage device 17.

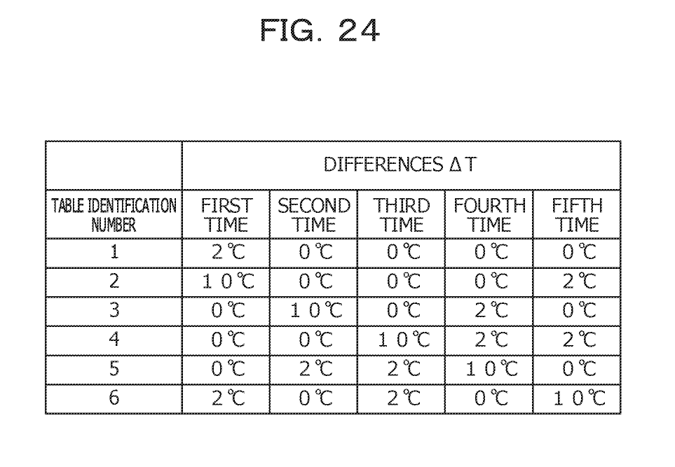

FIG. 24 is a diagram illustrating an example of the temperature change table. As illustrated in FIG. 24, in the temperature change table, the differences ΔT between absorbed air temperatures Ta and inside temperatures Ti of the electronic devices when a specific server (server selected in S45) operates are recorded for each execution of the sub-process.

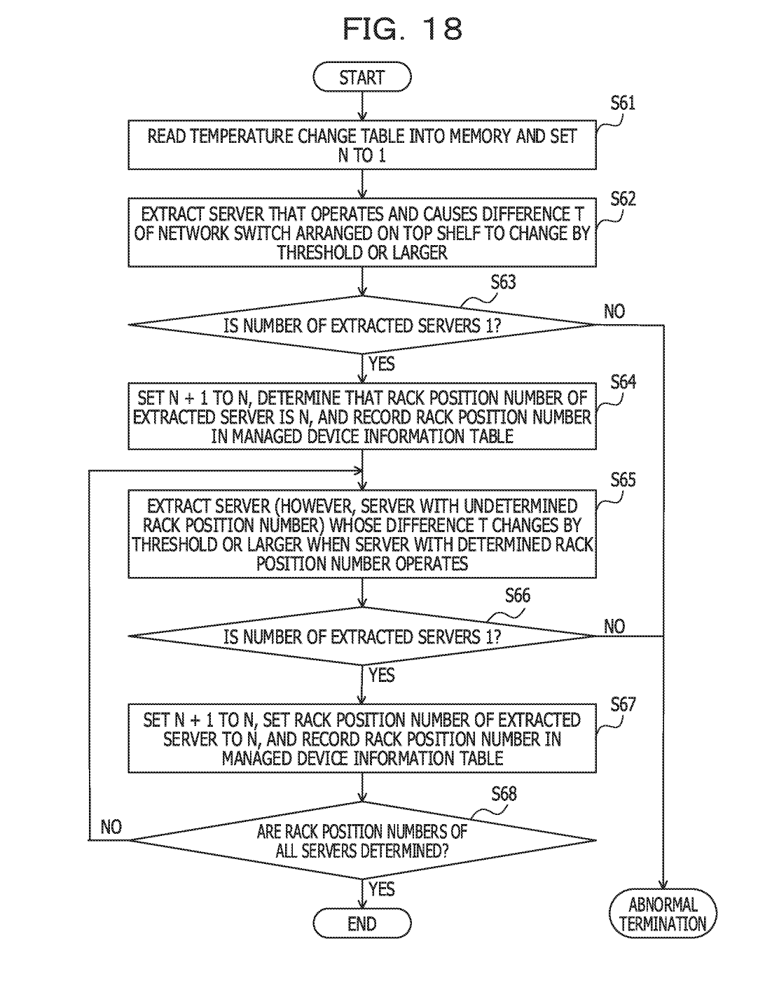

When generating the temperature change table, the managing device 11 starts a process indicated by the flowchart of FIG. 18.

In S61, the managing device 11 reads the temperature change table into the memory 19 from the storage device 17 and sets the variable N to 1 (N→1).

Next, the process proceeds to S62 and the managing device 11 references the temperature change table and extracts a server that is arranged on the top shelf of the rack 12 and operates and causes the difference ΔT of the network switch 21 to change by a threshold or larger.

In the second embodiment, the threshold is set to a value slightly lower than 2° C. The temperature change table illustrated in FIG. 24 indicates that the difference ΔT of the network switch 21 changes by the threshold or larger when the server with the table identification number 2 operates. Thus, the managing device 11 extracts the server with the table identification number 2.

Next, the process proceeds to S63 and the managing device 11 determines whether or not the number of extracted servers is 1. If the number of extracted servers is 1 (Yes in S63), the process proceeds to S64. If the number of extracted servers is 0 or 2 or larger (No in S63), the managing device 11 assumes that an abnormality occurred for some reason and the managing device 11 terminates the process (abnormal termination).

If the process proceeds from S63 to S64, the managing device 11 newly sets a value obtained by adding 1 to N to N (N+1→N). Then, the managing device 11 determines that a rack position number of the server extracted in S62 is N and the managing device 11 records the rack position number in the managed device information table.

Since the initial value of N is 1 as described above, the variable N becomes 2 in S64. Thus, the rack position number of the server 13 extracted in S62 and having the table identification number 2 is “2”. Specifically, the server 13 with the table identification number 2 is determined as a server arranged on the second top shelf of the rack 12.

Next, the process proceeds to S65 and the managing device 11 extracts a server (however, a server with an undetermined rack position number) whose difference ΔT changes by the threshold or larger when the server 13 with the rack position number determined in S64 operates.

The temperature management information table illustrated in FIG. 24 indicates that the difference ΔT between an absorbed air temperature Ta and inside temperature of a server with a table identification number 6 changes by the threshold or larger when the server with the table identification number 2 operates. Thus, the server with the table identification number 6 is extracted in S65.

Next, the process proceeds to S66 and the managing device 11 determines whether or not the number of extracted servers is 1. If the number of extracted servers is 1 (Yes in S66), the process proceeds to S67. If the number of extracted servers is 0 or 2 or larger (No in S66), the managing device 11 assumes that an abnormality occurred for some reason and the managing device 11 terminates the process (abnormal termination).

If the process proceeds from S66 to S67, the managing device 11 newly sets a value obtained by adding 1 to N to N (N+1→N). Then, the managing device 11 sets, to N, a rack position number of the server extracted in S65 and records the rack position number in the managed device information table.

Since the variable N becomes 2 in S64, the variable N becomes 3 in S67. Thus, the rack position number of the server with the table identification number 6 is “3”. Specifically, the server 13 with the table identification number 6 is determined as a server arranged on the third top shelf of the rack 12.

Next, the process proceeds to S68 and the managing device 11 determines whether or not rack position numbers of all the servers 13 were determined. If the managing device 11 determines that a rack position number of at least any of all the servers 13 is yet to be determined (No in S68), the process returns to S65 and the managing device 11 extracts a next server and determines a rack position number of the extracted server in S67.

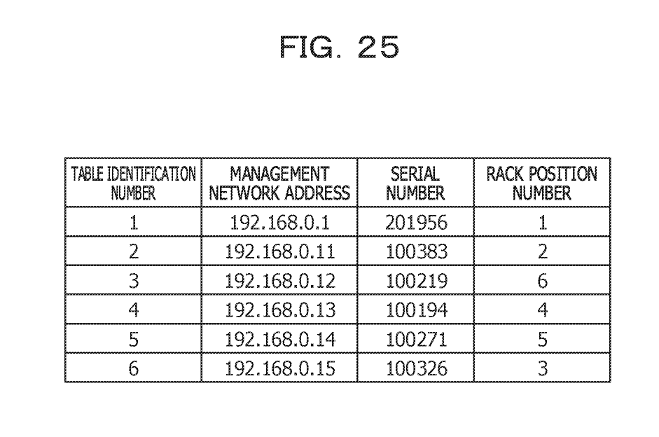

By repeating a loop of S65 to S68 in the aforementioned manner, the rack position numbers of all the servers 13 to be managed are determined and recorded in the managed device information table. FIG. 25 illustrates the managed device information table after the rack position numbers of all the servers 13 are recorded.

If the managing device 11 determines that the rack position numbers of all the servers 13 to be managed were determined (Yes in S68), the managing device 11 terminates the process (normal termination).

In the second embodiment, the temperature sensors 15a and 15b and BMCs 16 that are mounted as standard in the servers 13 are used, and the operation servers 13 are automatically associated with the positions of the operation servers 13 in the rack 12. In the second embodiment, a module storing positional information and a sensor for acquiring the positional information are not used or a specific device such as a PDU is not used, and thus effects of improving general versatility and causing installation cost to be relatively low are obtained.

### Third Embodiment

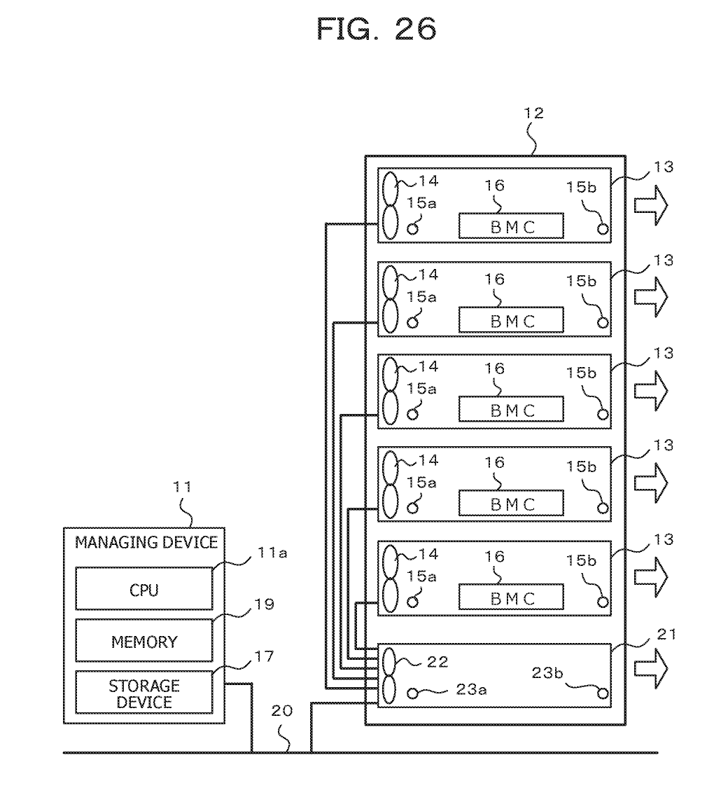

FIG. 26 is a schematic diagram illustrating an information processing system according to the third embodiment. In FIG. 26, parts that are the same as those illustrated in FIG. 15 are indicated by the same reference numbers and symbols as those illustrated in FIG. 15.

In the third embodiment, the network switch 21 is arranged on the bottom shelf (sixth shelf) of the rack 12, as illustrated in FIG. 26. The operation servers 13 are arranged on the first to fifth shelves of the rack 12.

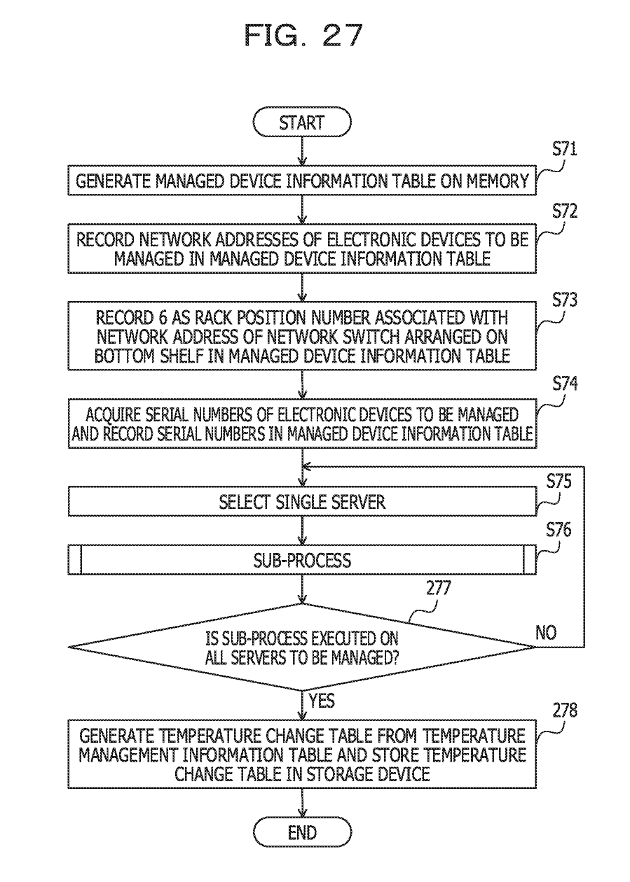

FIGS. 27, 28, and 29 are flowcharts of a control method to be executed by the information processing system according to the third embodiment.

In the third embodiment, specific management network addresses are set in the electronic devices (network switch 21 and servers 13) by the network administrator in advance, respectively. Specific serial numbers (IDs) are set in the electronic devices by the manufacturer in advance, respectively. The managing device 11 may access the electronic devices and acquire the serial numbers from the electronic devices.

In addition, the network switch 21 is identified to be arranged on the bottom shelf of the rack 12. The management network address of the network switch 21 is identified. It is assumed that the management network address of the network switch 21 is “192.168.0.1”.

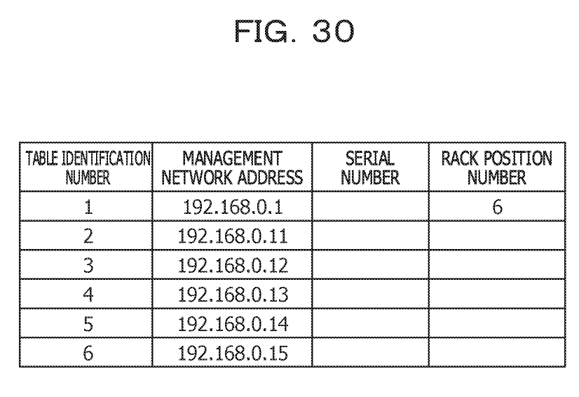

In S71, the managing device 11 generates a managed device information table on the memory 19. The managed device information table has a table identification number item, a management network address item, a serial number item, and a rack position number item, as illustrated in FIG. 30, for example.

Next, a process illustrated in FIG. 27 proceeds to S72 and the managing device 11 accesses, through the network 20, the electronic devices (network switch 21 and operation servers 13) to be managed and acquires the management network addresses of the electronic devices. Then, the managing device 11 records the acquired management network addresses in the managed device information table, as illustrated in FIG. 30.

In the example illustrated in FIG. 30, the table identification number of the network switch 21 is 1. The table identification numbers 2 to 6 are given to the operation servers 13 with the detected management network addresses in the order of the table identification numbers.

Next, the process proceeds to S73 and the managing device 11 records 6 as a rack position number of the network switch 21 arranged on the bottom shelf (sixth shelf) of the rack 12.

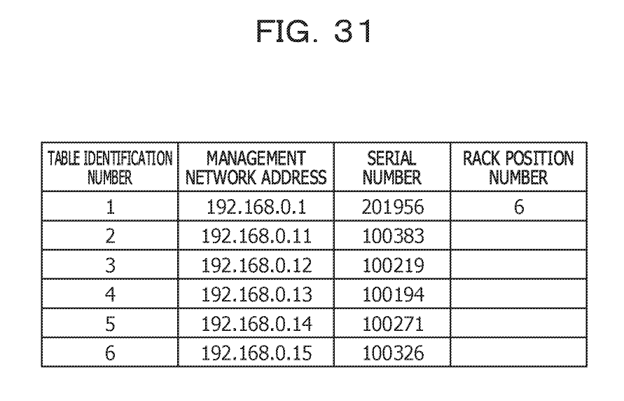

Then, the process proceeds to S74 and the managing device 11 accesses the electronic devices (network switch 21 and operation servers 13) through the network 20 and acquires the serial numbers (IDs) of the electronic devices. Then, the managing device 11 associates the serial numbers of the electronic devices with the table identification numbers and the management network addresses and records the serial numbers in the managed device information table, as illustrated in FIG. 31.

Next, the process proceeds to S75 and the managing device 11 selects a single server 13 from among the servers 13 to be managed. The managing device 11 selects the servers 13 in the order of the management network addresses. Thus, the server 13 with the management network address “192.168.0.11” (table identification number 2) is selected first.

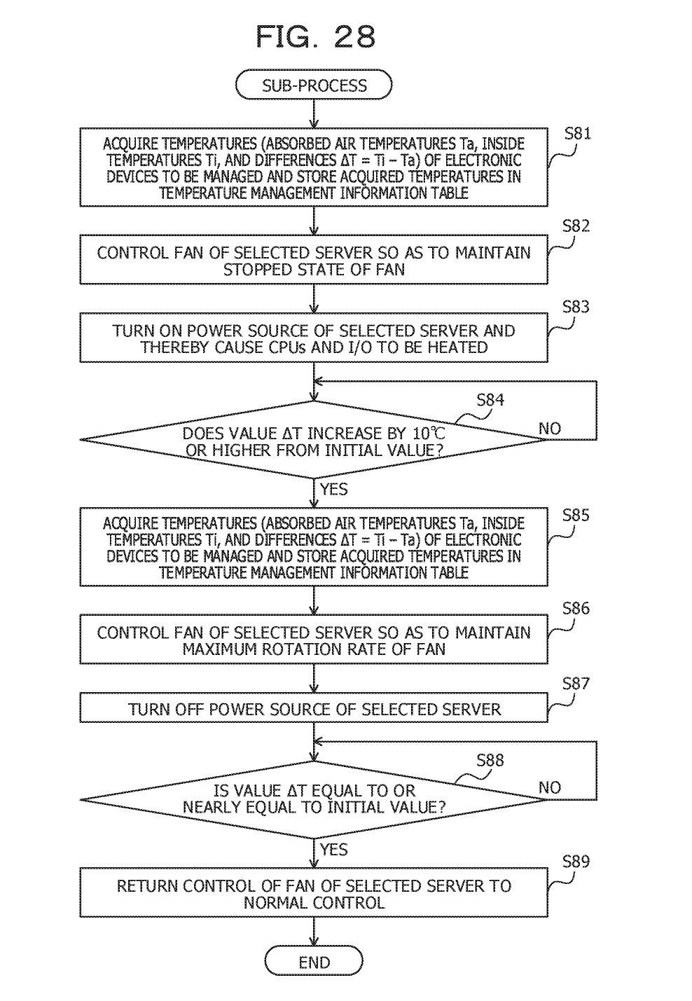

After that, the process proceeds to S76 and the managing device 11 executes a sub-process. The sub-process is described below with reference to FIG. 28.

In S81, the managing device 11 accesses, through the network 20, the electronic devices (network switch 21 and operation servers 13) to be managed and acquires absorbed air temperatures Ta and inside temperatures Ti of the electronic devices.

Then, the managing device 11 calculates the differences ΔT (=Ti−Ta) between the inside temperatures Ti and the absorbed air temperatures Ta for the electronic devices and generates a temperature management information table on the memory 19.

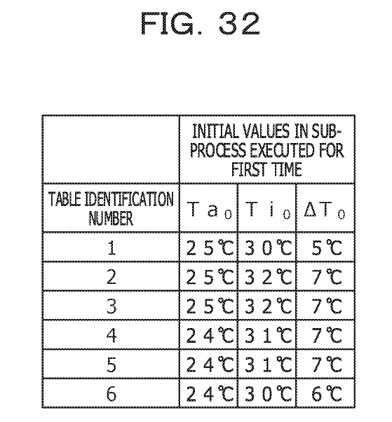

FIG. 32 is a diagram illustrating an example of the temperature management information table. As illustrated in FIG. 32, in the temperature management information table, the absorbed air temperatures Ta and inside temperatures Ti of the electronic devices (network switch 21 and operation servers 13) and the differences ΔT between the absorbed air temperatures Ta and the inside temperatures Ti are recorded in the temperature management information table for the table identification numbers.

Next, the process proceeds to S82 and the managing device 11 stops the fan 14 of the selected server 13 (server with the table identification number 2 in the sub-process executed for the first time) through the network 20 and the BMC 16 of the selected server 13.

Next, the process proceeds to S83 and the managing device 11 turns on a power source of the selected server 13 through the network 20 and the BMC 16 of the selected server 13 and thereby causes the selected server 13 to operate. Due to the operation of the server 13, the CPUs and I/O of the server 13 are heated and the inside temperature Ti of the server 13 increases.

Next, the process proceeds to S84 and the managing device 11 stands by (looping) until the difference ΔT of the selected server 13 increases by a predetermined temperature (of 10° C. in this example) or higher from an initial value of the difference ΔT. When the difference ΔT of the selected server 13 increases by the predetermined temperature or higher from the initial value, the process proceeds to S85.

In S85, the managing device 11 accesses, through the network 20, the electronic devices (network switch 21 and operation servers 13) to be managed and acquires the absorbed air temperatures Ta and inside temperatures Ti of the electronic devices. The managing device 11 calculates the differences ΔT between the absorbed air temperatures Ta and inside temperatures Ti of the electronic devices. Then, the managing devices stores the absorbed air temperatures Ta, the inside temperatures Ti, and the differences ΔT in the temperature management information table.

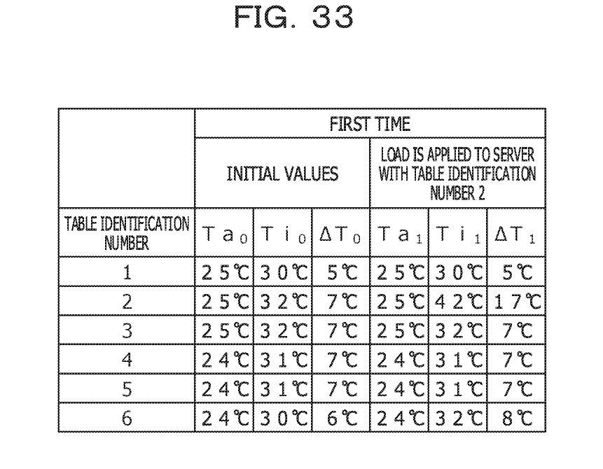

FIG. 33 illustrates the temperature management information table in which absorbed air temperatures Ta₁, inside temperatures Ti₁, and the differences ΔT₁ between the absorbed air temperature Ta₁ and the inside temperatures Ti₁ when the server 13 with the table identification number 2 operates are recorded.

Next, the process proceeds to S86 and the managing device 11 controls a rotation rate of the fan 14 of the selected server 13 through the network 20 and the BMC 16 of the selected server 13 so as to set the rotation rate to the maximum rotation rate. Subsequently, in S87, the managing device 11 turns off the power source of the selected server 13.

Next, the process proceeds to S88 and the managing device 11 stands by (looping) until the difference ΔT of the server 13 that operates in S83 becomes equal to or nearly equal to the initial value (or the difference ΔT before the server 13 operates). When the difference ΔT of the server 13 that operates in S83 becomes equal to or nearly equal to the initial value, the process proceeds to S89 and the managing device 11 returns control of the fan 14 of the server 13 to normal control (so that the rotation rate is based on the inside temperature Ti, for example). Then, the managing device 11 terminates the sub-process and causes the process to proceed to S77 of the flowchart illustrated in FIG. 27.

In S77, the managing device 11 determines whether or not the sub-process was executed on all the servers 13 to be managed. If the managing device 11 determines that the sub-process is yet to be executed on at least any of all the servers 13 to be managed (No in S77), the process returns to S75 and the managing device 11 selects a next server 13 from among servers 13 that are yet to be subjected to the sub-process. After that, in S76, the sub-process (of S81 to S89) illustrated in FIG. 28 is executed on the selected server 13.

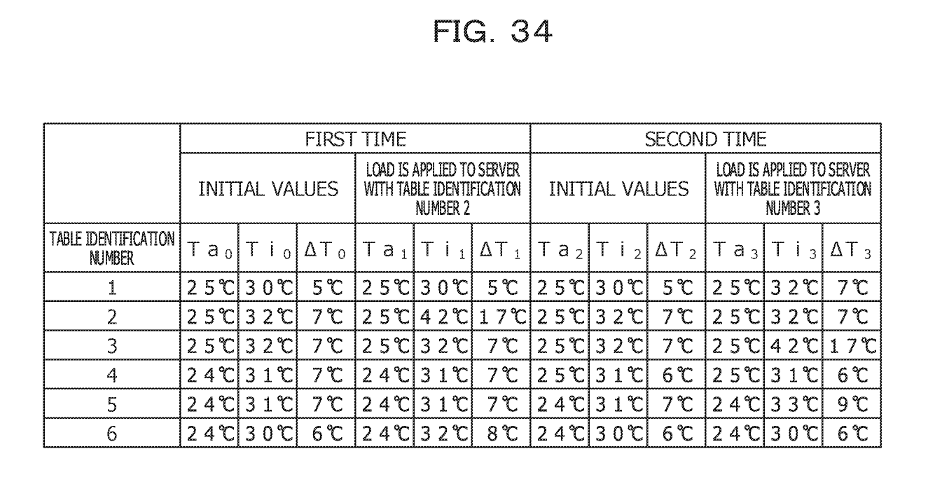

FIG. 34 illustrates initial values of absorbed air temperatures Ta and inside temperatures Ti obtained in the sub-process executed for the first and second times, the differences ΔT between the initial values of the temperatures Ta and Ti obtained in the sub-process executed for the first and second times, values of absorbed air temperatures Ta and inside temperatures Ti obtained when specific servers (servers selected in S75) operate, and the differences ΔT between the temperatures Ta and Ti obtained when the specific servers operate.

As illustrated in FIG. 34, initial values of absorbed air temperatures Ta, initial values of inside temperatures Ti, the differences ΔT between the initial values of the temperatures Ta and Ti, values of absorbed air temperatures Ta and inside temperatures Ti when a server operates, and the differences ΔT between the temperatures Ta and Ti when the server operates, are recorded in the temperature management information table for each execution of the sub-process.

If the managing device 11 determines that the sub-process was executed on all the servers 13 to be managed (Yes in S77), the process proceeds to S78. Then, the managing device 11 generates a temperature change table from the temperature management information table and stores the generated temperature change table in the storage device 17.

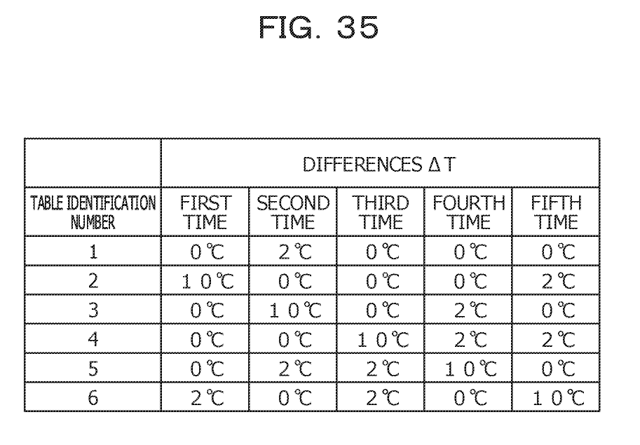

FIG. 35 is a diagram illustrating an example of the temperature change table. As illustrated in FIG. 35, in the temperature change table, the differences ΔT between absorbed air temperatures Ta and inside temperatures Ti of the electronic devices when a specific server (server selected in S75) are recorded for each execution of the sub-process.

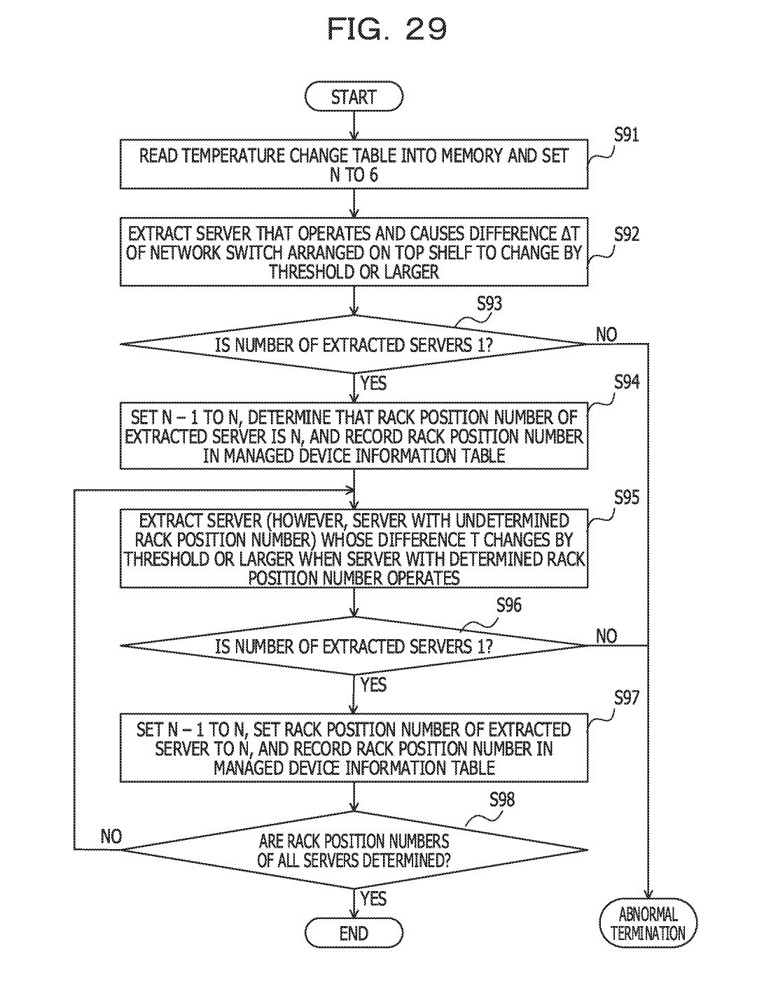

When generating the temperature change table, the managing device 11 starts a process indicated by the flowchart of FIG. 29.

In S91, the managing device 11 reads the temperature change table into the memory 19 from the storage device 17 and sets the variable N to 6 (N→6).

Next, the process proceeds to S92 and the managing device 11 references the temperature change table and extracts a server that operates and causes the difference ΔT of the network switch 21 arranged on the bottom shelf of the rack 12 to change by a threshold or larger.

In the third embodiment, the threshold is set to a value slightly lower than 2° C. The temperature change table illustrated in FIG. 35 indicates that the difference ΔT of the network switch 21 (with the table identification number 1) when the server with the table identification number 3 operates changes by the threshold or larger. Thus, the managing device 11 extracts the server 3 with the table identification number 3.

Next, the process proceeds to S93 and the managing device 11 determines whether or not the number of extracted servers is 1. If the number of extracted servers is 1 (Yes in S93), the process proceeds to S94. If the number of extracted servers is 0 or 2 or larger (No in S93), the managing device 11 assumes that an abnormality occurred for some reason and the managing device 11 terminates the process (abnormal termination).

If the process proceeds from S93 to S94, the managing device 11 newly sets a value obtained by subtracting 1 from N to N (N−1→N). Then, the managing device 11 determines that a rack position number of the server extracted in S92 is N and the managing device 11 records the rack position number in the managed device information table.

Since the initial value of N is 6 as described above, the variable N becomes 5 in S94. Thus, the rack position number of the server 13 extracted in S92 and having the table identification number 3 is “5”. Specifically, the server 13 with the table identification number 3 is determined as a server arranged on the fifth top shelf of the rack 12.

Next, the process proceeds to S95 and the managing device 11 extracts a server (however, a server with an undetermined rack position number) whose difference ΔT changes by the threshold or larger when the server 13 with the rack position number determined in S94 operates.

The temperature management information table illustrated in FIG. 35 indicates that the difference ΔT of the server with the table identification number 5 changes by the threshold or larger when the server with the table identification number 3 operates. Thus, the server with the table identification number 5 is extracted in S95.

Next, the process proceeds to S96 and the managing device 11 determines whether or not the number of extracted servers is 1. If the number of extracted servers is 1 (Yes in S96), the process proceeds to S97. If the number of extracted servers is 0 or 2 or larger (No in S96), the managing device 11 assumes that an abnormality occurred for some reason and the managing device 11 terminates the process (abnormal termination).

If the process proceeds from S96 to S97, the managing device 11 newly sets a value obtained by subtracting 1 from N to N (N−1→N). Then, the managing device 11 sets, to N, a rack position number of the server extracted in S95 and records the rack position number in the managed device information table.

Since the variable N becomes 5 in S94, the variable N becomes 4 in S97. Thus, the rack position number of the server with the table identification number 5 is “4”. Specifically, the server 13 with the table identification number 5 is determined as a server arranged on the fourth top shelf of the rack 12.

Next, the process proceeds to S98 and the managing device 11 determines whether or not rack position numbers of all the servers 13 were determined. If the managing device 11 determines that a rack position number of at least any of all the servers 13 is yet to be determined (No in S98), the process returns to S95 and the managing device 11 extracts a next server in S95 and determines a rack position number of the extracted server in S97.

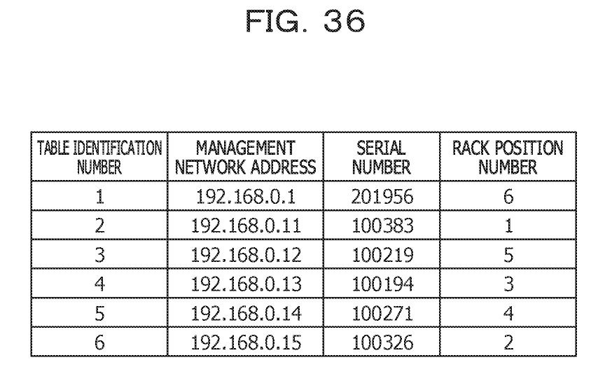

By repeating a loop of S95 to S98 in the aforementioned manner, the rack position numbers of all the servers 13 to be managed are determined and recorded in the managed device information table. FIG. 36 illustrates the managed device information table after the rack position numbers of all the servers 13 are recorded.

If the managing device 11 determines that the rack position numbers of all the servers 13 to be managed were determined (Yes in S98), the managing device 11 terminates the process (normal termination).

In the third embodiment, the temperature sensors 15a and 15b and BMCs 16 that are mounted as standard in the servers 13 are used and the operation servers 13 are automatically associated with the positions of the operation servers 13 in the racks 12. In the third embodiment, a module storing positional information and a sensor for acquiring the positional information are not used or a specific device such as a PDU is not used, and thus effects of improving general versatility and causing installation cost to be relatively low are obtained.

### Fourth Embodiment

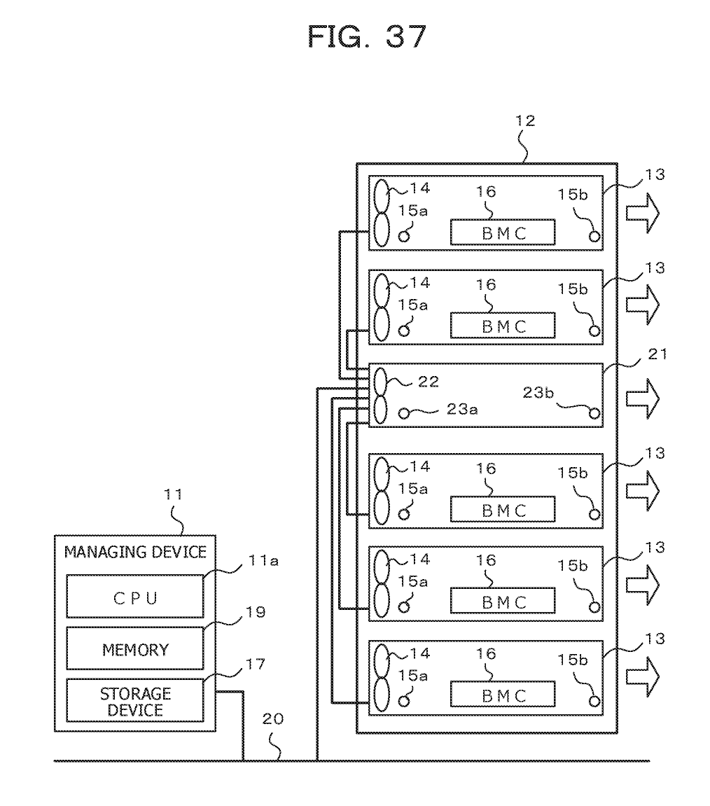

FIG. 37 is a schematic diagram illustrating an information processing system according to a fourth embodiment. In FIG. 37, parts that are the same as those illustrated in FIG. 15 are indicated by the same reference numbers and symbols as those illustrated in FIG. 15.

In the fourth embodiment, as illustrated in FIG. 37, the network switch 21 is arranged on a middle shelf of the rack 12. The operation servers 13 are arranged on the other shelves of the rack 12.

The managing device 11 is connected to the operation servers 13 through the network switch 21. The network switch 21 has the fan 22, the temperature sensor 23a for detecting a temperature on the side of air absorption, and the temperature sensor 23b for detecting temperatures of the operation servers 13.

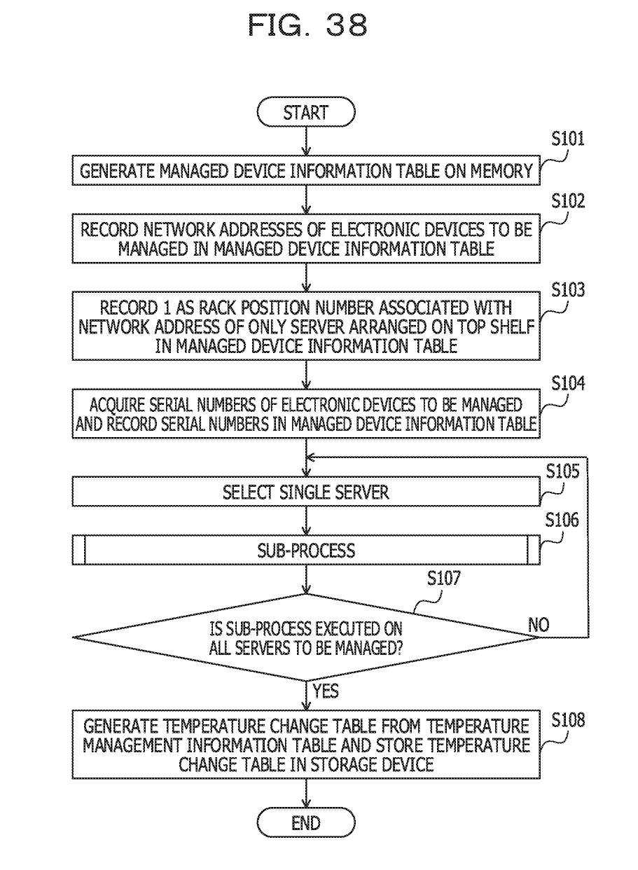

FIGS. 38, 39, 40, and 41 are flowcharts of a control method to be executed by the information processing system according to the fourth embodiment.

In the fourth embodiment, specific management network addresses are set in the electronic devices (network switch 21 and servers 13) by the network administrator in advance, respectively. Specific serial numbers (IDs) are set in the electronic devices by the manufacturer in advance, respectively. The managing device 11 may access the electronic devices and acquire the serial numbers from the electronic devices.

It is assumed that a management network address of an operation server 13 arranged on the top shelf (uppermost shelf) of the rack 12 is identified in advance. It is assumed that the management network address of the operation server 13 arranged on the top shelf (uppermost shelf) of the rack 12 is “192.168.0.11”.

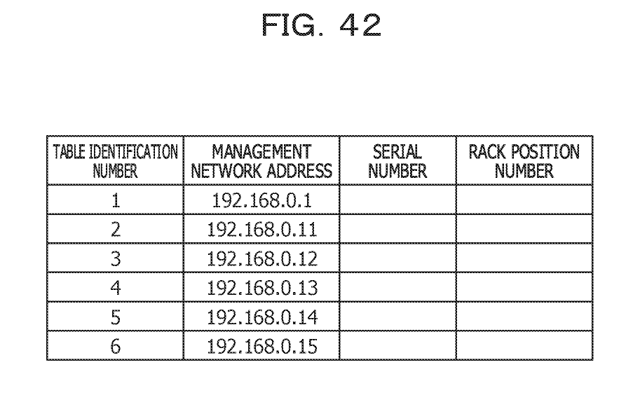

In S101, the managing device 11 generates a managed device information table on the memory 19. The managed device information table has a table identification number item, a management network address item, a serial number item, and a rack position number item, as illustrated in FIG. 42, for example.

Next, a process illustrated in FIG. 38 proceeds to S102 and the managing device 11 accesses, through the network 20, the electronic devices (network switch 21 and operation servers 13) to be managed and acquires the management network addresses of the electronic devices. Then, the managing device 11 records the management network addresses in the managed device information table, as illustrated in FIG. 42.

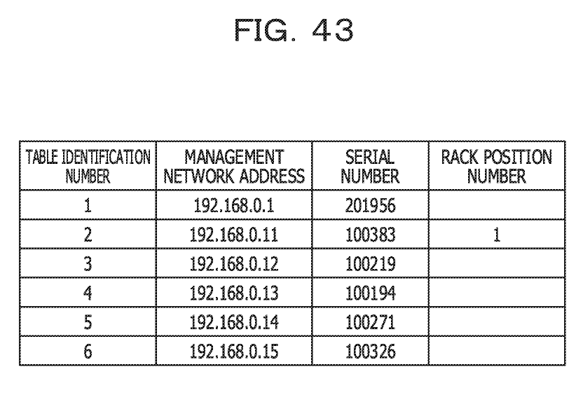

Next, the process proceeds to S103 and the managing device 11 records 1 as a rack position number of the operation server 13 arranged on the top shelf of the rack 12, as illustrated in FIG. 43. As described above, the management network address of the operation server 13 arranged on the top shelf of the rack 12 is identified in advance. The managed device information table illustrated in FIG. 43 indicates that the server 13 with the table identification number 2 is arranged on the top shelf of the rack 12.

Next, the process proceeds to S104 and the managing device 11 accesses, through the network 20, the electronic devices (network switch 21 and operation servers 13) to be managed and acquires the serial numbers (IDs) of the electronic devices. Then, the managing device 11 associates the serial numbers of the electronic devices with the table identification numbers and the management network addresses and records the serial numbers in the managed device information table, as illustrated in FIG. 43.

Next, the process proceeds to S105 and the managing device 11 selects a single server 13 from among the servers 13 to be managed. The managing device 11 selects the servers 13 in the order of the management network addresses. Thus, the server 13 with the management network address “192.168.0.11” (table identification number 2) is selected first.

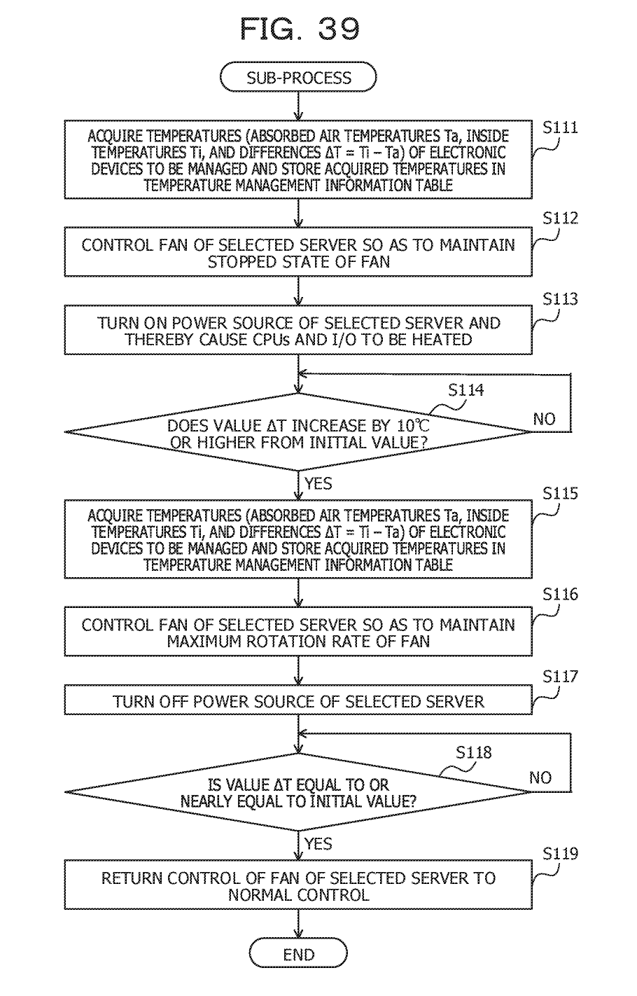

After that, the process proceeds to S46 and the managing device 11 executes a sub-process. The sub-process is described below with reference to FIG. 39.

In S111, the managing device 11 accesses, through the network 20, the electronic devices (network switch 21 and operation servers 13) to be managed and acquires absorbed air temperatures Ta and inside temperatures Ti of the electronic devices.

Then, the managing device 11 calculates the differences ΔT (=Ti−Ta) between the inside temperatures Ti and the absorbed air temperatures Ta for the electronic devices and generates a temperature management information table on the memory 19.

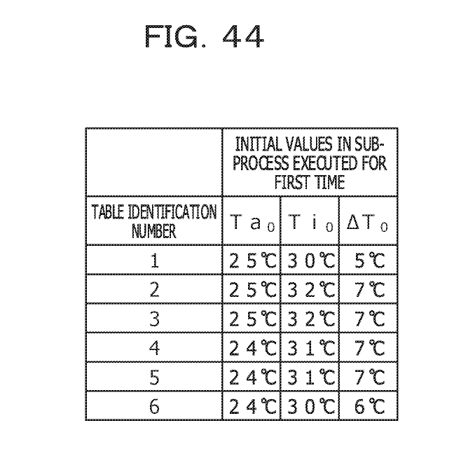

FIG. 44 is a diagram illustrating an example of the temperature management information table. As illustrated in FIG. 44, in the temperature management information table, the absorbed air temperatures Ta and inside temperatures Ti of the electronic devices (network switch 21 and operation servers 13) and the differences ΔT between the absorbed air temperatures Ta and the inside temperatures Ti are recorded for the table identification numbers.

Next, the process proceeds to S112 and the managing device 11 stops the fan 14 of the selected server 13 (server 13 with the table identification number 2 in the sub-process executed for the first time) through the network 20 and the BMC 16 of the selected server 13.

Next, the process proceeds to S113 and the managing device 11 turns on a power source of the selected server 13 through the network 20 and the BMC 16 of the selected server 13 and thereby causes the server 13 to operate. Due to the operation of the server 13, the CPUs and I/O of the server 13 are heated and the inside temperature Ti of the server 13 increases.

Next, the process proceeds to S114 and the managing device 11 stands by (looping) until the difference ΔT of the selected server 13 increases by a predetermined temperature (of 10° C. in this example) or higher from an initial value of the difference ΔT. When the difference ΔT of the selected server 13 increases by the predetermined temperature or higher from the initial value, the process proceeds to S115.

In S115, the managing device 11 accesses, through the network 20, the electronic devices (network switch 21 and operation servers 13) to be managed and acquires the absorbed air temperatures Ta and inside temperatures Ti of the electronic devices. The managing device 11 calculates the differences ΔT between the absorbed air temperatures Ta and inside temperatures Ti of the electronic devices. Then, the managing device 11 stores the absorbed air temperatures Ta, the inside temperatures Ti, and the differences ΔT in the temperature management information table.

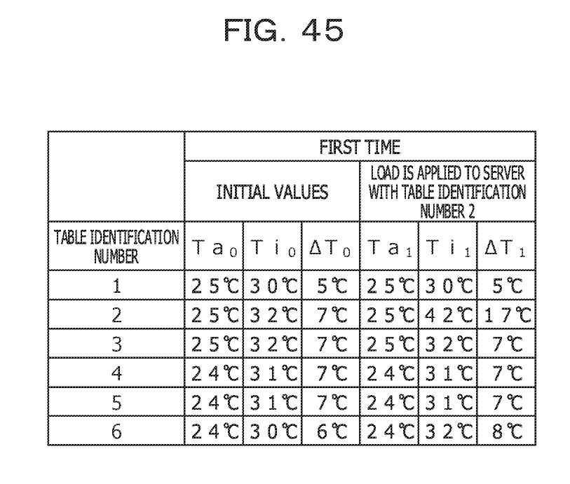

FIG. 45 illustrates the temperature management information table in which absorbed air temperatures Ta₁, inside temperatures Ti₁, and the differences ΔT₁ between the absorbed air temperatures Ta₁ and the inside temperatures Ti₁ when the server 13 with the table identification number 2 operates are recorded.

Next, the process proceeds to S116 and the managing device 11 controls a rotation rate of the fan 14 of the selected server 13 through the network 20 and the BMC 16 of the selected server 13 so as to set the rotation rate to the maximum rotation rate. Subsequently, in S117, the managing device 11 turns off the power source of the selected server 13.

Next, the process proceeds to S118 and the managing device 11 stands by (looping) until the difference ΔT of the server 13 that operates in S113 becomes equal to or nearly equal to the initial value (or the difference ΔT before the server 13 operates). When the difference ΔT of the server 13 that operates in S113 becomes equal to or nearly equal to the initial value, the process proceeds to S119 and the managing device 11 returns control of the fan 14 of the server 13 to normal control (so that the rotation rate of the fan 14 is based on the inside temperature Ti, for example). Then, the managing device 11 terminates the sub-process and causes the process to proceed to S107 of the flowchart illustrated in FIG. 38.

In S107, the managing device 11 determines whether or not the sub-process was executed on all the servers 13 to be managed. If the managing device 11 determines that the sub-process is yet to be executed on at least any of all the servers 13 to be managed (No in S107), the process returns to S105 and the managing device 11 selects a next server 13 from among servers 13 that are yet to be subjected to the sub-process. After that, in S106, the managing device 11 executes the sub-process (of S111 to S119) illustrated in FIG. 39.

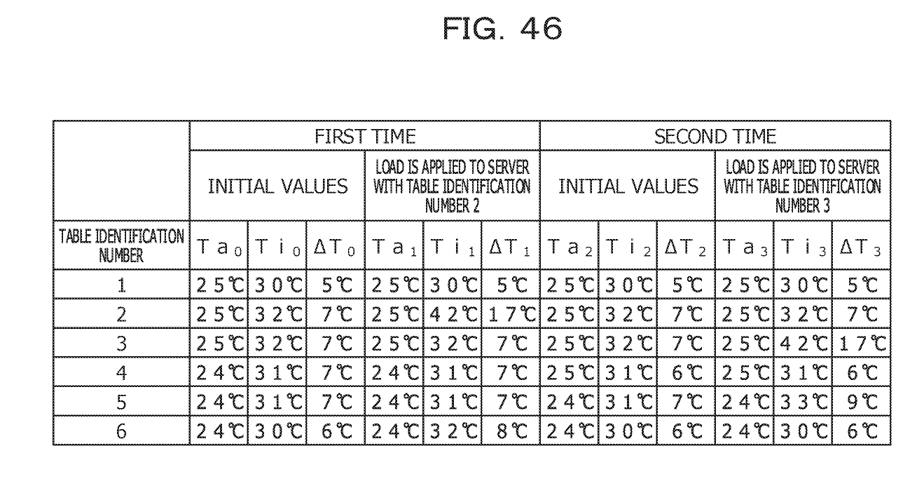

FIG. 46 illustrates initial values of absorbed air temperatures Ta and inside temperatures Ti obtained in the sub-process executed for the first and second times, the differences ΔT between the initial values of the temperatures Ta and Ti obtained in the sub-process executed for the first and second times, values of absorbed air temperatures Ta and inside temperatures Ti obtained when specific servers (servers selected in S105) operate, and the differences ΔT between the temperatures Ta and Ti obtained when the specific servers operate.

As illustrated in FIG. 46, initial values of absorbed air temperatures Ta, initial values of inside temperatures Ti, the differences ΔT between the initial values of the temperatures Ta and Ti, values of absorbed air temperatures Ta and inside temperatures Ti when a server operates, and the differences ΔT between the temperatures Ta and Ti when the server operates, are recorded in the temperature management information table for each execution of the sub-process.

If the managing device 11 determines that the sub-process was executed on all the servers 13 to be managed (Yes in S107), the process proceeds to S108. Then, the managing device 11 generates a temperature change table from the temperature management information table and stores the generated temperature change table in the storage device 17.

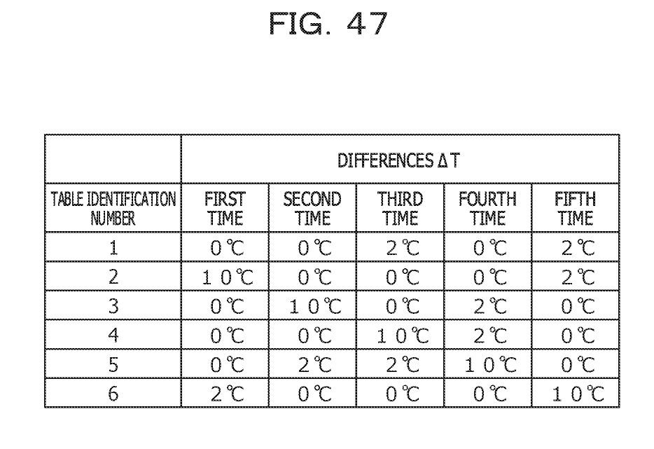

FIG. 47 is a diagram illustrating an example of the temperature change table. As illustrated in FIG. 47, in the temperature change table, the differences ΔT between absorbed air temperatures Ta and inside temperatures Ti of the electronic devices when a specific server (selected in S105) operates are recorded for each execution of the sub-process.

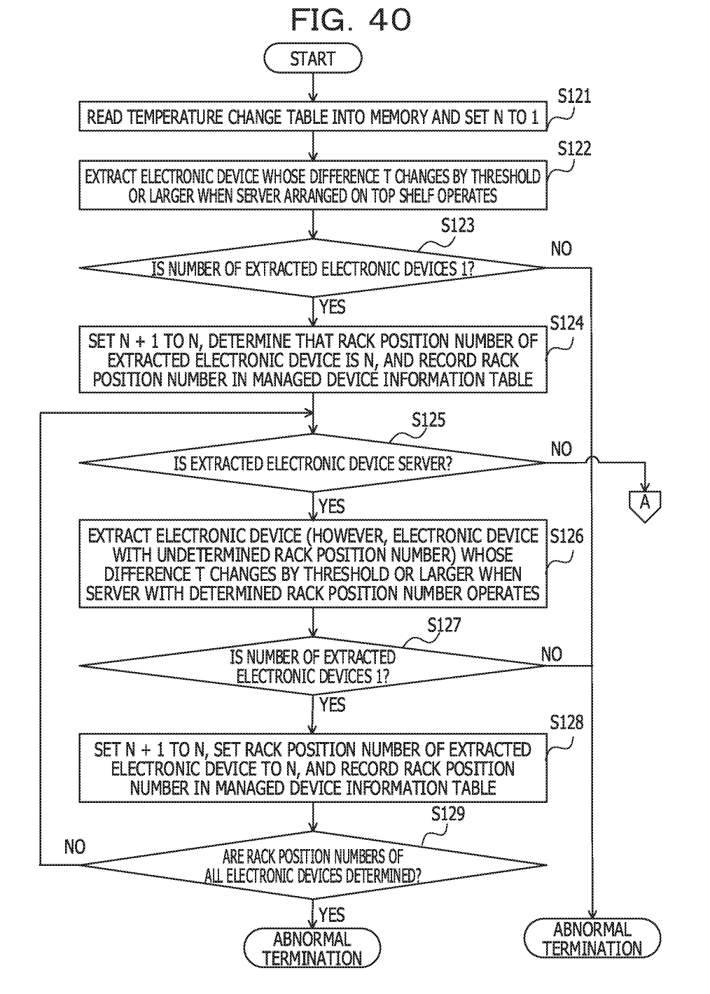

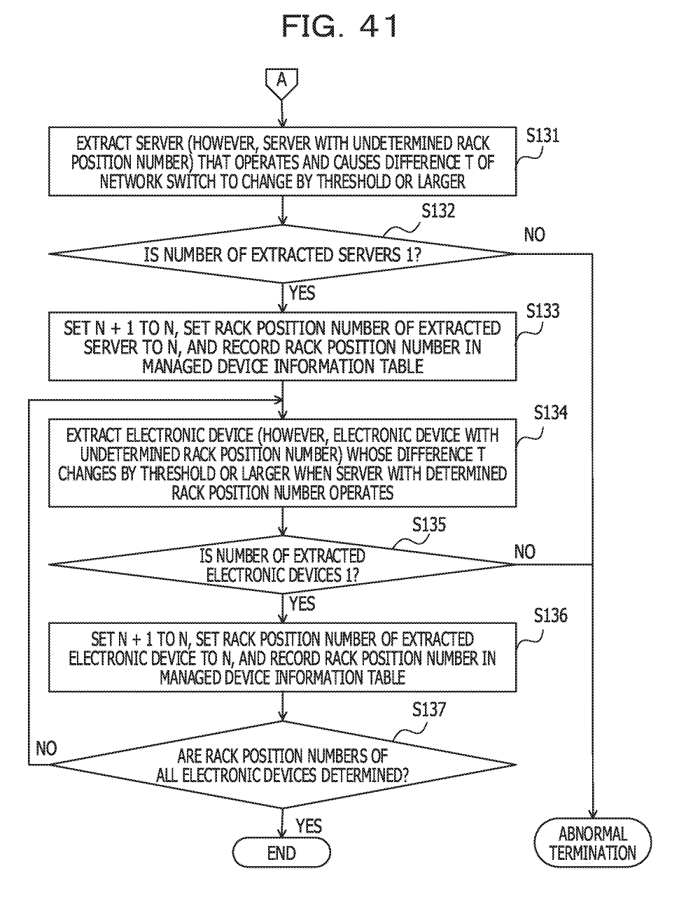

When generating the temperature change table, the managing device 11 starts a process indicated by the flowchart of FIGS. 40 and 41.

In S121, the managing device 11 reads the temperature change table into the memory 19 from the storage device 17 and sets the variable N to 1 (N→1).

Next, the process proceeds to S122 and the managing device 11 references the temperature change table and extracts an electronic device whose difference ΔT changes by a threshold or larger when the server 13 (server with the table identification number 2) arranged on the top shelf of the rack 12 operates.

In the fourth embodiment, the threshold is set to a value slightly lower than 2° C. The temperature change table illustrated in FIG. 47 indicates that the difference ΔT of the server 13 with the table identification number 6 changes by the threshold or larger when the server with the table identification number 2 operates. Thus, the managing device 11 extracts the server with the table identification number 6.

Next, the process proceeds to S123 and the managing device 11 determines whether or not the number of extracted electronic devices is 1. If the number of extracted electronic devices is 1 (Yes in S123), the process proceeds to S124. If the number of extracted electronic devices is 0 or 2 or larger (No in S123), the managing device 11 assumes that an abnormality occurred for some reason and the managing device 11 terminates the process (abnormal termination).

If the process proceeds from S123 to S124, the managing device 11 newly sets a value obtained by adding 1 to N to N (N+1→N). Then, the managing device 11 determines that a rack position number of the electronic device extracted in S122 is N and the managing device 11 records the rack position number in the managed device information table.

Since the initial value of N is 1 as described above, the variable N becomes 2 in S124. Thus, the rack position number of the electronic device extracted in S122 and having the table identification number 6 is “2”. Specifically, the electronic device with the table identification number 6 is determined to be arranged on the second top shelf of the rack 12.

Next, the process proceeds to S125 and the managing device 11 determines whether or not the electronic device extracted in S122 is a server 13. In the determination, the management network addresses and the serial numbers are used.

For example, the management network addresses assigned to the operation servers 13 and the network switch 21 are stored in the managing device 11 in advance. Thus, the managing device 11 may determine, based on the management network addresses, that the electronic device with the table identification number 6 is the operation server 13. If the managing device 11 determines that the extracted electronic device is the server (Yes in S125), the process proceeds from S125 to S126.

In S126, the managing device 11 extracts an electronic device with an undetermined rack position number from electronic devices whose differences ΔT change by the threshold or larger when the server (server with the table identification number 6) with the determined rack position number operates. In the example illustrated in FIG. 47, when the server 13 with the table identification number 6 operates, the differences ΔT of the electronic devices with the table identification numbers 1 and 2 change by the threshold or larger. Since the rack position number of the electronic device with the table identification number 2 is determined to be “1”, the electronic device extracted in S126 has the table identification number 1.

After that, in S127, the managing device 11 determines whether or not the number of extracted electronic devices is 1. If the number of extracted electronic devices is 1 (Yes in S127), the process proceeds to S128. If the number of extracted electronic devices is 0 or 2 or larger (No in S127), the managing device 11 assumes that an abnormality occurred for some reason and the managing device 11 terminates the process (abnormal termination).

If the process proceeds from S127 to S128, the managing device 11 newly sets a value obtained by adding 1 to N to N (N+1→N). Then, the managing device 11 sets, to N, a rack position number of the electronic device extracted in S127 and records the rack position number in the managed device information table.

Since the variable N becomes 2 in S124, the variable N becomes 3 in S128. Thus, the rack position number of the electronic device with the table identification number 1 is “3”. Specifically, the electronic device with the table identification number 1 is determined to be arranged on the third top shelf of the rack 12.

Next, the process proceeds to S129 and the managing device 11 determines whether or not rack position numbers of all the electronic devices were determined. If the managing device 11 determines that a rack position number of at least any of all the electronic devices is yet to be determined (No in S129), the process returns to S125 and the managing device 11 extracts a next electronic device.

In the aforementioned case, the rack position numbers of the electronic devices with the table identification numbers 1, 6, and 2 are already determined, but the rack position numbers of the electronic devices with the table identification numbers 3, 4, and 5 are yet to be determined. Thus, the process proceeds from S129 to S125.

If the managing device 11 determines that the rack position numbers of all the electronic devices were determined in S129, the network switch 21 is not detected and thus the managing device 11 assumes that an abnormality occurred for some reason and the managing device 11 terminates the process (abnormal termination).

If the electronic device with the table identification number 1 is extracted in S126 and the process proceeds from S129 to S125, the managing device 11 determines that the extracted electronic device is the network switch 21 based on the management network addresses and the serial numbers. Thus, the process proceeds from S125 to S131.

In S131, the managing device 11 extracts a server 13 whose rack position number is yet to be determined and that causes the difference ΔT of the electronic device (network switch 21) with the table identification number 1 to change by the threshold or larger. In the example illustrated in FIG. 47, the servers with the table identification numbers 4 and 6 cause the difference ΔT of the electronic device with the table identification number 1 to change by the threshold or larger. Since the rack position number of the server with the table identification number 6 is already determined to be “2”, the server with the table identification number 4 is extracted in S131.

Next, the process proceeds to S132 and the managing device 11 determines whether or not the number of extracted servers is 1. If the number of extracted servers is 1 (Yes in S132), the process proceeds to S133. If the number of extracted servers is 0 or 2 or larger (No in S132), the managing device 11 assumes that an abnormality occurred for some reason and the managing device 11 terminates the process (abnormal termination).

In S133, the managing device 11 newly sets a value obtained by adding 1 to N to N (N+1→N). Then, the managing device 11 sets, to N, a rack position number of the server extracted in S131 and records the rack position number in the managed device information table.

Since the variable N becomes 3 in S128, the variable N becomes 4 in S133. Thus, the rack position number of the server with the table identification number 4 is “4”.

Next, the process proceeds to S134 and the managing device 11 extracts an electronic device (however, an electronic device with an undetermined rack position number) whose difference ΔT changes by the threshold or larger when the server with the rack position number determined in S133 operates.

The temperature change table illustrated in FIG. 47 indicates that the differences ΔT of the electronic devices with the table identification numbers 1 and 5 change by the threshold or larger when the server with the table identification number 4 operates. Since the rack position number of the electronic device with the table identification number 1 is already determined to be “3”, the electronic device with the table identification number 5 is extracted in S134.

Next, the process proceeds to S135 and the managing device 11 determines whether or not the number of extracted electronic devices is 1. If the number of extracted electronic devices is 1 (Yes in S135), the process proceeds to S136. If the number of extracted electronic devices is 0 or 2 or larger (No in S136), the managing device 11 assumes that an abnormality occurred for some reason and the managing device 11 terminates the process (abnormal termination).

Next, in S136, the managing device 11 newly sets a value obtained by adding 1 to N to N (N+1→N). Then, the managing device 11 sets, to N, a rack position number of the electronic device extracted in S134 and records the rack position number in the managed device information table.

Since the variable N becomes 4 in S133, the variable N becomes 5 in S136. Thus, the rack position number of the electronic device (server 13) with the table identification number 5 is “5”.

Next, the process proceeds to S137 and the managing device 11 determines whether or not rack position numbers of all the electronic devices to be managed were determined. If the managing device 11 determines that a rack position number of at least any of all the electronic devices to be managed is yet to be determined (No in S137), the process returns to S134 and the managing device 11 extracts an electronic device whose rack position number will be determined next. Subsequently, in S136, the managing device 11 determines the rack position number. In this manner, the rack position numbers of all the electronic devices to be managed are determined. If the managing device 11 determines that the rack position numbers of all the electronic devices to be managed were determined in S137, the managing device 11 terminates the process (normal termination).

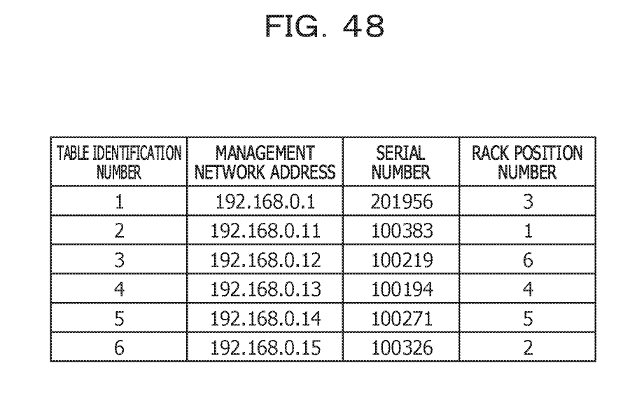

FIG. 48 illustrates the managed device information table after the rack position numbers of the electronic devices (network switch 21 and operation servers 13) are recorded.

In the fourth embodiment, the temperature sensors 15a and 15b and BMCs 16 that are mounted as standard in the servers 13 are used, and the operation servers 13 are automatically associated with the positions of the operation servers 13 in the racks 12. In the fourth embodiment, a module storing positional information and a sensor for acquiring the positional information are not used or a specific device such as a PDU is not used, and thus effects of improving general versatility and causing installation cost to be relatively low are obtained.

### Fifth Embodiment

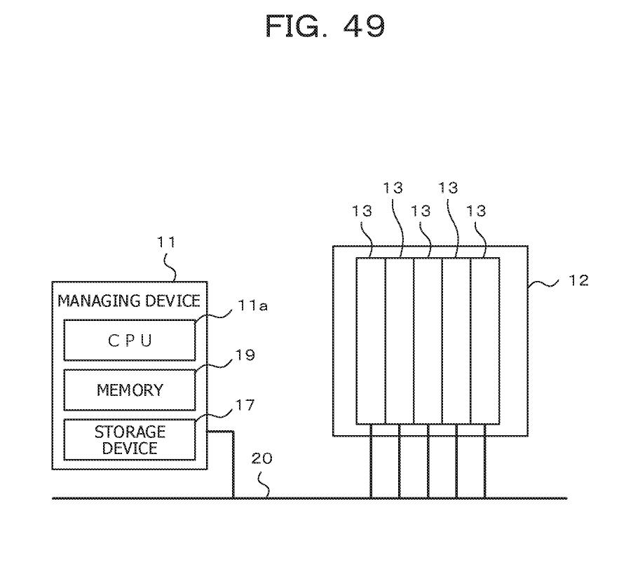

FIG. 49 is a schematic diagram illustrating an information processing system according to a fifth embodiment. In FIG. 49, parts that are the same as those illustrated in FIG. 1 are indicated by the same reference numbers and symbols as those illustrated in FIG. 1.

In the fifth embodiment, five servers 13 are arranged side by side in a rack 12, as illustrated in FIG. 47. In the same manner as the first embodiment, the servers 13 each have a fan 14, temperature sensors 15a and 15b and a BMC 16 (refer to FIG. 1). The managing device 11 is connected to the servers 13 through the network 20.

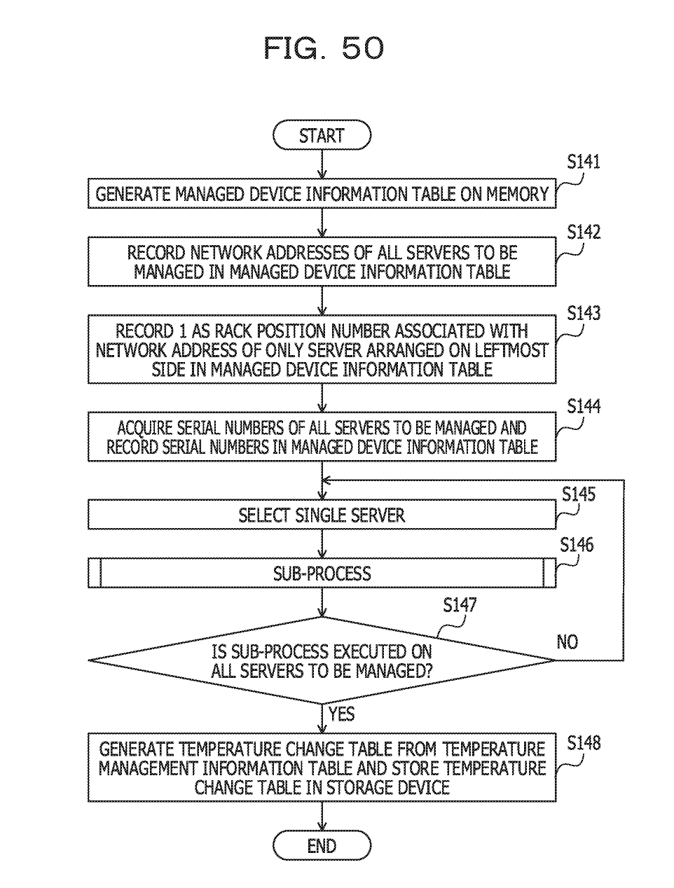

FIGS. 50, 51, and 52 are flowcharts of a control method to be executed by the information processing system according to the fifth embodiment.

In the fifth embodiment, specific management network addresses are set in the electronic devices (network switch 21 and servers 13) by the network administrator in advance, respectively. Specific serial numbers (IDs) are set in the electronic devices by the manufacturer in advance, respectively. The managing device 11 may acquire the serial numbers from the operation servers 13 through the BMCs 16. It is assumed that a management network address of an operation server 13 arranged on the leftmost side of the rack 12 is identified in advance.

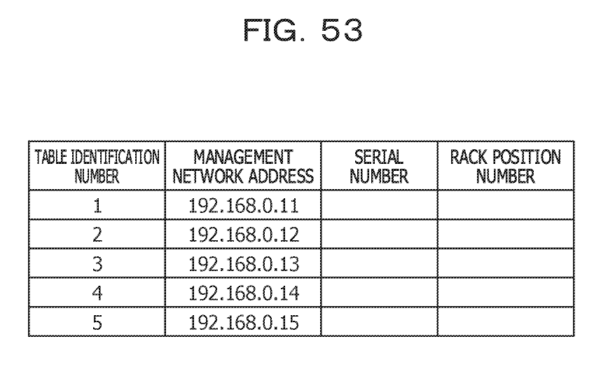

In S141, the managing device 11 generates a managed device information table on the memory 19. The managed device information table has a table identification number item, a management network address item, a serial number item, and a rack position number item, as illustrated in FIG. 53, for example.

Next, a process illustrated in FIG. 50 proceeds to S142 and the managing device 11 accesses, through the network 20, all the servers 13 to be managed and acquires the management network addresses of the servers 13. Then, the managing device 11 records the management network addresses in the managed device information table, as illustrated in FIG. 53.

In the example illustrated in FIG. 53, table identification numbers are given to the operation servers 13 with the detected management network addresses in the order of the management network addresses.

Next, the process proceeds to S143 and the managing device 11 records 1 as a rack position number of the operation server 13 arranged on the leftmost side of the rack 12, as illustrated in FIG. 8.

The rack position number 1 indicates that the operation server 13 is arranged on the leftmost side of the rack 12. As described above, the management network address of the operation server 13 arranged on the leftmost side of the rack 12 is identified in advance. In this example, the operation server 13 with the management network address “192.168.0.11” is arranged on the leftmost side of the rack 12.

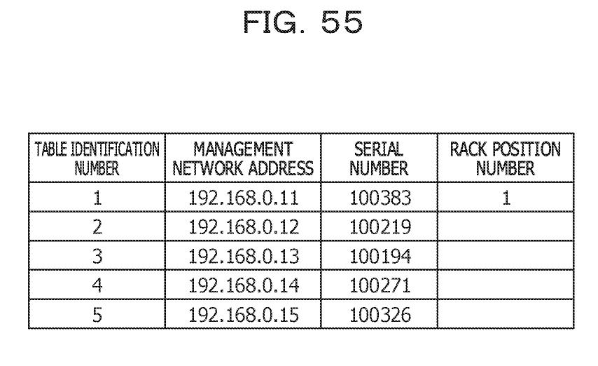

Next, the process proceeds to S144 and the managing device 11 accesses the operation servers 13 through the network 20 and acquires the serial numbers (IDs) of the servers 13. Then, the managing device 11 associates the serial numbers of the servers 13 with the table identification numbers and the management network addresses and records the serial numbers in the managed device information table, as illustrated in FIG. 55.

Next, the process proceeds to S145 and the managing device 11 selects a single server 13 from among the servers 13 to be managed. The managing device 11 selects the servers 13 in the order of the management network addresses. Thus, the server 13 with the management network address “192.168.0.11” (table identification number 1) is selected first.

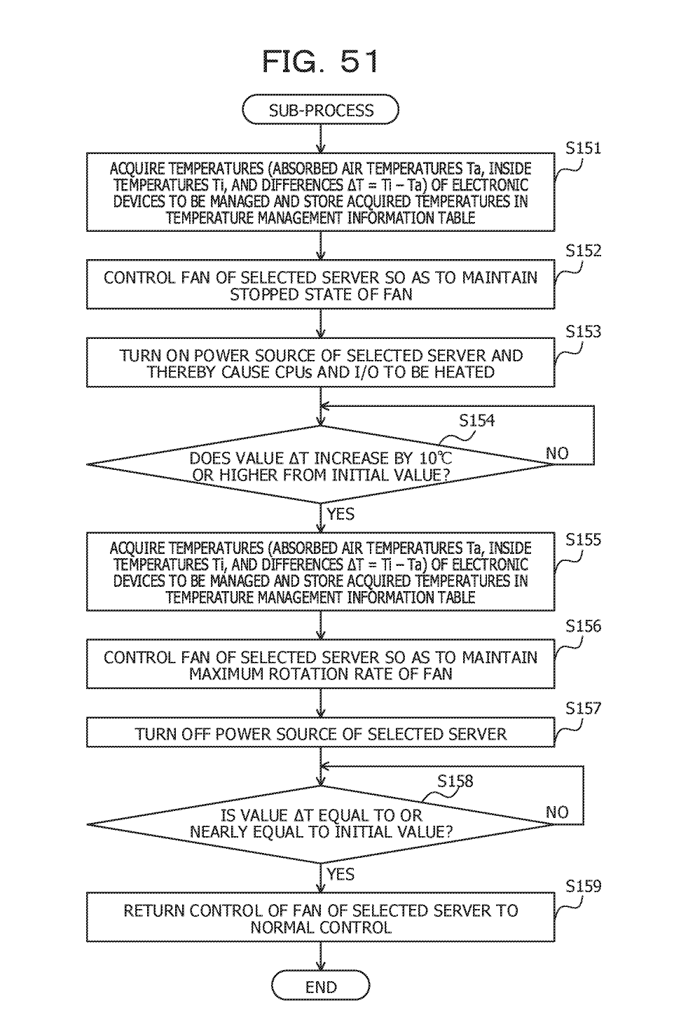

After that, the process proceeds to S146 and the managing device 11 executes a sub-process. The sub-process is described below with reference to FIG. 51.

In S151, the managing device 11 accesses, through the network 20, all the servers 13 to be managed and acquires absorbed air temperatures Ta and inside temperatures Ti of the servers 13. Then, the managing device 11 calculates the differences ΔT (=Ti−Ta) between the inside temperatures Ti and the absorbed air temperatures Ta for the operation servers 13 and generates a temperature management information table on the memory 19.

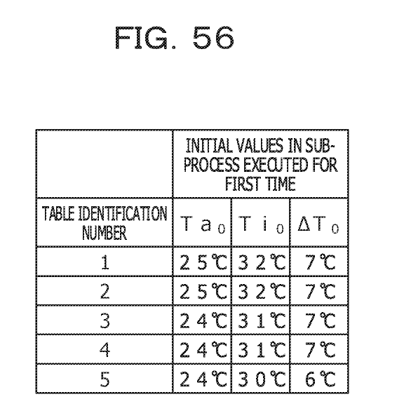

FIG. 56 is a diagram illustrating an example of the temperature management information table. As illustrated in FIG. 56, in the temperature management information table, the absorbed air temperatures Ta and inside temperatures Ti of the servers 13 and the differences ΔT between the absorbed air temperatures Ta and the inside temperatures Ti are recorded for the table identification numbers.

Next, the process proceeds to S152 and the managing device 11 stops the fan 14 of the selected server 13 (server with the table identification number 1 in the sub-process executed for the first time) through the network 20.

Next, the process proceeds to S153 and the managing device 11 turns on a power source of the selected server 13 through the network 20 and thereby causes the selected server 13 to operate. Due to the operation of the server 13, the CPUs and I/O of the server 13 are heated and the inside temperature Ti of the server 13 increases.

Next, the process proceeds to S154 and the managing device 11 stands by (looping) until the difference ΔT of the selected server 13 increases by a predetermined temperature (of 10° C. in this example) or higher from an initial value of the difference ΔT. When the difference ΔT of the selected server 13 increases by the predetermined temperature or higher from the initial value, the process proceeds to S155.

In S155, the managing device 11 accesses, through the network 20, all the servers 13 to be managed and acquires the absorbed air temperatures Ta and inside temperatures Ti of the servers 13. The managing device 11 calculates the differences ΔT between the absorbed air temperatures Ta and inside temperatures Ti of all the servers 13 to be managed. Then, the managing device 11 stores the absorbed air temperatures Ta, the inside temperatures Ti, and the differences ΔT in the temperature management information table.

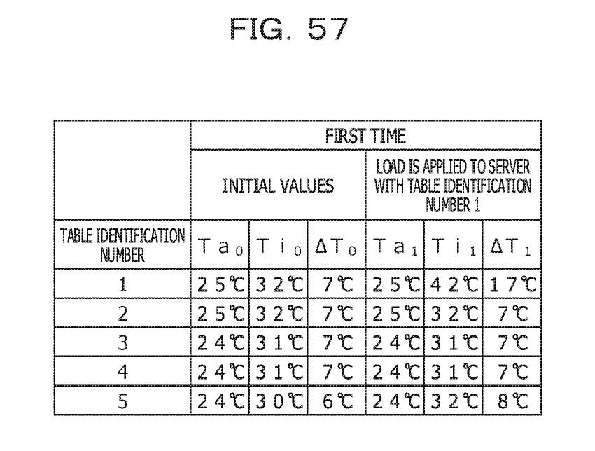

FIG. 57 illustrates the temperature management information table in which absorbed air temperatures Ta₁, inside temperatures Ti₁, and the differences ΔT₁ between the absorbed air temperatures Ta₁ and the inside temperatures Ti₁ when the server 13 with the table identification number 1 operates are recorded.

Next, the process proceeds to S156 and the managing device 11 controls a rotation rate of the fan 14 of the selected server 13 through the network 20 so as to set the rotation rate to the maximum rotation rate. Subsequently, in S157, the managing device 11 turns off the power source of the selected server 13.

Next, the process proceeds to S158 and the managing device 11 stands by (looping) until the difference ΔT of the server 13 that operates in S153 becomes equal to or nearly equal to an initial value (or the difference ΔT before the server 13 operates). When difference ΔT of the server 13 that operates in S153 becomes equal to or nearly equal to the initial value, the process proceeds to S159 and the managing device 11 returns control of the fan 14 of the server 13 to normal control (so that the rotation rate of the fan 14 is based on the inside temperature Ti, for example). Then, the managing device 11 terminates the sub-process and causes the process to proceed to S147 of the flowchart illustrated in FIG. 50.

In S147, the managing device 11 determines whether or not the sub-process was executed on all the servers 13 to be managed. If the managing device 11 determines that the sub-process is yet to be executed on at least any of all the servers 13 to be managed, the process returns to S145 and the managing device 11 selects a next server 13 from among servers 13 that are yet to be subjected to the sub-process. After that, in S146, the sub-process (of S151 to S159) illustrated in FIG. 51 is executed on the selected server 13.

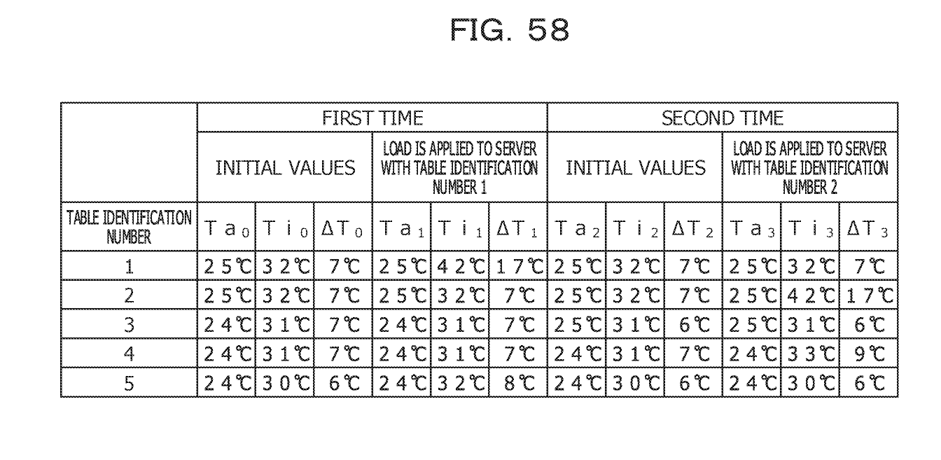

FIG. 58 illustrates initial values of absorbed air temperatures Ta and inside temperatures Ti obtained in the sub-process executed for the first and second times, the differences ΔT between the initial values of the temperatures Ta and Ti obtained in the sub-process executed for the first and second times, values of absorbed air temperatures Ta and inside temperatures Ti obtained when specific servers (servers selected in S145) operate, and the differences ΔT between the temperatures Ta and Ti obtained when the specific servers operate.

As illustrated in FIG. 58, initial values of absorbed air temperatures Ta, initial values of inside temperatures Ti, the differences ΔT between the initial values of the temperatures Ta and Ti, values of absorbed air temperatures Ta and inside temperatures Ti when a server operates, and the differences ΔT between the temperatures Ta and Ti when the server operates, are recorded in the temperature management information table for each execution of the sub-process.

If the managing device 11 determines that the sub-process was executed on all the servers 13 to be managed (Yes in S147), the process proceeds to S148. Then, the managing device 11 generates a temperature change table from the temperature management information table and stores the generated temperature change table in the storage device 17.

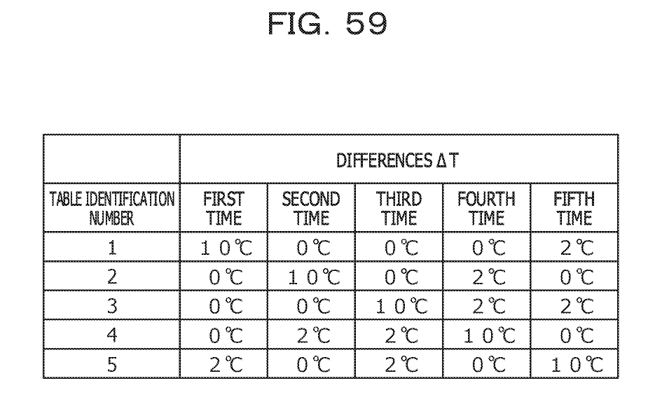

FIG. 59 is a diagram illustrating an example of the temperature change table. As illustrated in FIG. 59, in the temperature change table, the differences ΔT between absorbed air temperatures Ta and inside temperatures Ti of all the servers 13 when a specific server (server selected in S145) operates are recorded for each execution of the sub-process.

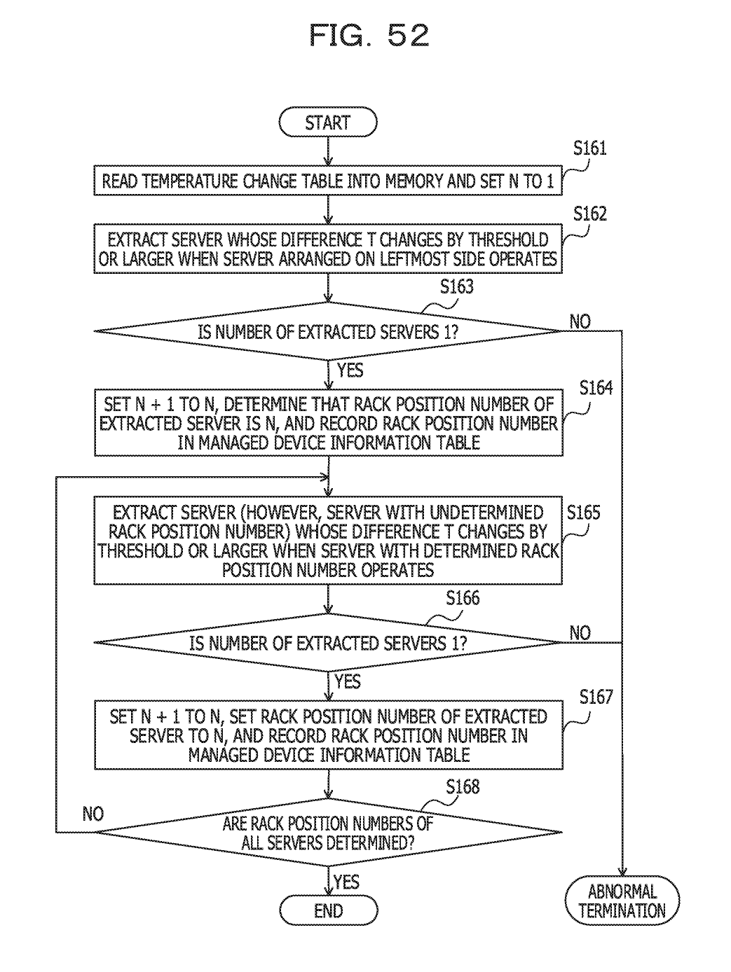

When generating the temperature change table, the managing device 11 starts a process indicated by the flowchart of FIG. 52.

In S161, the managing device 11 reads the temperature change table into the memory 19 from the storage device 17 and sets the variable N to 1 (N→1).

Next, the process proceeds to S162 and the managing device 11 references the temperature change table and extracts a server whose difference ΔT changes by a threshold or larger when the server arranged on the leftmost side of the rack 12 operates.

In the fifth embodiment, the threshold is set to a value slightly lower than 2° C. The temperature change table illustrated in FIG. 59 indicates that the difference ΔT of the server with the table identification number 5 changes by the threshold or larger when the server with the table identification number 1 operates. Thus, the managing device 11 extracts the server with the table identification number 5.

Next, the process proceeds to S163 and the managing device determines whether or not the number of extracted servers is 1. If the number of extracted servers is 1 (Yes in S163), the process proceeds to S164. If the number of extracted servers is 0 or 2 or larger (No in S163), the managing device 11 assumes that an abnormality occurred for some reason and the managing device 11 terminates the process (abnormal termination).

If the process proceeds from S163 to S164, the managing device 11 newly sets a value obtained by adding 1 to N to N (N+1→N). Then, the managing device 11 determines that a rack position number of the server extracted in S162 is N and the managing device 11 records the rack position number in the managed device information table.

Since the initial value of N is 1 as described above, the variable N becomes 2 in S164. Thus, the rack position number of the server 13 extracted in S162 and having the table identification number 5 is “2”. Specifically, the server 13 with the table identification number 5 is determined as a server arranged on the second top shelf of the rack 12.

Next, the process proceeds to S165 and the managing device 11 extracts a server (however, a server with an undetermined rack position number) whose difference ΔT changes by the threshold or larger when the server 13 with the rack position number determined in S164 operates.

The temperature management information table illustrated in FIG. 59 indicates that the differences ΔT of the servers with the table identification numbers 1 and 3 change by the threshold or larger when the server with the table identification number 5 operates. Since the rack position number of the server with the table identification number 1 is already determined to be “1”, the server with the table identification number 3 is extracted in S165.

Next, the process proceeds to S166 and the managing device 11 determines whether or not the number of extracted servers is 1. If the number of extracted servers is 1 (Yes in S166), the process proceeds to S167. If the number of extracted servers is 0 or 2 or larger (No in S166), the managing device 11 assumes that an abnormality occurred for some reason and the managing device 11 terminates the process (abnormal termination).

If the process proceeds from S166 to S167, the managing device 11 newly sets a value obtained by adding 1 to N to N (N+1→N). Then, the managing device 11 sets, to N, a rack position number of the server extracted in S165 and records the rack position number in the managed device information table.

Since the variable N becomes 2 in S164, the variable N becomes 3 in S167. Thus, the rack position number of the server with the table identification number 3 is “3”. Specifically, the server 13 with the table identification number 3 is determined as a server arranged on the third shelf of the rack 12 from the left.

Next, the process proceeds to S168 and the managing device 11 determines whether or not rack position numbers of all the servers 13 were determined. If the managing device 11 determines that a rack position number of at least any of all the servers 13 is yet to be determined (No in S168), the process returns to S165 and the managing device 11 extracts a next server. Subsequently, in S167, the managing device 11 determines a rack position number of the extracted server.

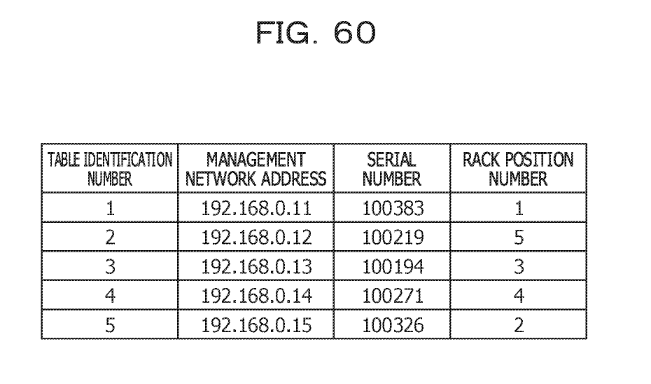

By repeating the loop of S165 to S168 in the aforementioned manner, the rack position numbers of all the servers 13 to be managed are determined and recorded in the managed device information table. FIG. 60 illustrates the managed device information table after the rack position numbers of all the servers 13 are recorded.

If the managing device 11 determines that the rack position numbers of all the servers 13 to be managed were determined (Yes in S168), the managing device 11 terminates the process (normal termination).

In the fifth embodiment, the temperature sensors 15a and 15b and BMCs 16 that are mounted as standard in the servers 13 are used, and the operation servers 13 are automatically associated with the positions of the operation servers 13 in the racks 12. In the fifth embodiment, a module storing positional information and a sensor for acquiring the positional information are not used or a specific device such as a PDU is not used, and thus effects of improving general versatility and causing installation cost to be relatively low are obtained.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A control method executed by an information processing system that includes a plurality of electronic devices arranged side by side in a single direction in a common housing and having temperature sensors and includes a managing device coupled to the plurality of electronic devices, the control method comprising:
activating an electronic device among the plurality of electronic devices based on a predetermined order;
receiving temperature information from the temperature sensors included in the plurality of electronic devices, the temperature information indicating temperatures of the plurality of electronic devices that are measured when any of the plurality of electronic devices operates and another one or more electronic devices excluding the operating electronic device do not operate; and
identifying positions of the plurality of electronic devices arranged in the common housing, based on amounts of changes in temperatures of the plurality of electronic devices calculated using the temperature information.

2. The control method according to claim 1,
wherein the identifying includes identifying the positions of the plurality of electronic devices arranged in the common housing by referencing a temperature management information table in which the amounts of the changes in the temperatures are associated with identification information indicating the positions of the electronic devices arranged in the common housing.

3. The control method according to claim 1, wherein the activating includes:
turning on a power source of the electronic device among the plurality of electronic devices, and
operating a processor included in the electronic device among the plurality of electronic devices.

4. The control method according to claim 1,
wherein the activating includes activating an electronic device that is among the plurality of electronic devices arranged side by side in the single direction in the common housing and is arranged on the outermost side of the common housing.

5. The control method according to claim 1,
wherein the predetermined order is an order of network addresses assigned to the plurality of electronic devices.

6. The control method according to claim 1, further comprising
turning off a power source of the activated electronic device when a temperature received from one of activated electronic devices among the plurality of electronic devices exceeds a predetermined temperature.

7. The control method according to claim 1,
wherein the electronic devices includes fans configured to cause air to flow through the electronic devices, and
wherein the control method further comprises stopping a fan of any of activated electronic devices among the plurality of electronic devices during the time when any of the activated electronic devices among the plurality of electronic devices operates.

8. The control method according to claim 1,
wherein the temperature sensors include first sensors configured to detect temperatures of the air flowing in the electronic devices and second sensors configured to detect temperatures of the electronic devices.

9. The control method according to claim 1,
wherein at least one of the plurality of electronic devices is a server.

10. The control method according to claim 1,
wherein at least one of the plurality of electronic devices is a network switch.

11. An information processing system comprising:
a plurality of electronic devices having temperature sensors and arranged side by side in a single direction in a common housing; and
a managing device coupled to the plurality of electronic devices and configured to:
activate an electronic device among the plurality of electronic devices based on a predetermined order;
receive temperature information from the temperature sensors included in the plurality of electronic devices, the temperature information including temperatures of the plurality of electronic devices that are measured when any of the plurality of electronic devices operates and another one or more electronic devices excluding the operating electronic device do not operate; and
identifying positions of the plurality of electronic devices arranged in the common housing, based on amounts of changes in temperatures of the plurality of electronic devices calculated using the temperature information.

12. The information processing system according to claim 11,
wherein the managing device is configured to identify the positions of the plurality of electronic devices arranged in the common housing by referencing a temperature management information table in which the amounts of the changes in the temperatures are associated with identification information indicating the positions of the electronic devices arranged in the common housing.

13. The information processing system according to claim 11, wherein the managing device is configured to:
turn on a power source of the electronic device among the plurality of electronic devices, and
operate a processor included in the electronic device among the plurality of electronic devices.

14. A non-transitory computer-readable storage medium storing a program that causes a processor included in a managing device to execute a process, the managing device being coupled to a plurality of electronic devices having temperature sensors, respectively, the process comprising:
activating an electronic device among the plurality of electronic devices based on a predetermined order;
receiving temperature information from the temperature sensors included in the plurality of electronic devices, the temperature information including temperatures of the plurality of electronic devices that are measured when any of the plurality of electronic devices operates and another one or more electronic devices excluding the operating electronic device do not operate; and
identifying positions of the plurality of electronic devices arranged in the common housing, based on amounts of changes in temperatures of the plurality of electronic devices calculated using the temperature information.
